(19) United States
(12) Patent Application Publication
(10) Pub. No.: US 2026/0305251 A1
(43) Pub. Date: Oct. 1, 2026

(54) ELECTROSTATIC CHUCK, SUBSTRATE TREATING APPARATUS AND METHOD OF MANUFACTURING DISPLAY DEVICE USING THE SAME

(71) Applicant: Samsung Display Co., Ltd., Yongin-si (KR)

(72) Inventors: DONGHO PARK, Yongin-si (KR); TAEYOUNG PARK, Yongin-si (KR); SUKJU KANG, Yongin-si (KR); BYUNG MOO KIM, Yongin-si (KR); BYEONG-HYUN KIM, Yongin-si (KR); JUN-HEE LEE, Yongin-si (KR); Jaeheung Cho, Yongin-si (KR)

(21) Appl. No.: 19/440,201

(22) Filed: Jan. 5, 2026

(30) Foreign Application Priority Data
Mar. 31, 2025 (KR) 10-2025-0041623

(51) Int. Cl. H10P 72/72; H10K 71/00; H10P 72/50

(52) U.S. Cl. CPC H10P 72/722; H10K 71/00; H10P 72/53

(57) ABSTRACT

An electrostatic chuck includes: a body portion having a through hole; a cushion layer on the body portion, a first inspection hole in the cushion layer overlapping the through hole in a plan view; an electrode layer on the cushion layer, a second inspection hole in the electrode layer overlapping the first inspection hole in the plan view; and a dielectric layer on the electrode layer and having a surface exposed through the second inspection hole. At least a portion of the dielectric layer is transparent.

### CROSS-REFERENCE TO RELATED APPLICATION

The present application claims priority to and the benefit of Korean Patent Application No. 10-2025-0041623, filed on Mar. 31, 2025, in the Korean Intellectual Property Office, the entire disclosure of which is incorporated herein by reference.

### BACKGROUND

### 1. Field

Aspects of embodiments of the present disclosure relate to an electrostatic chuck, a substrate treating apparatus, and a method of manufacturing a display device using the same.

### 2. Description of the Related Art

Generally, in a manufacturing process of a semiconductor device or a display device, an electrostatic chuck is used to transfer or hold a target substrate, such as a semiconductor wafer or a glass substrate, to be adsorbed. The electrostatic chuck may have a structure in which the target substrate is attracted to an upper portion of the electrostatic chuck by a force (e.g., an electrostatic force) generated by a potential charged to the electrode provided inside the chuck and the target substrate.

In a process chamber, an upper target substrate adsorbed onto an upper electrostatic chuck and a lower target substrate adsorbed onto a lower electrostatic chuck may be bonded. For example, bonding between the upper target substrate and the lower target substrate may be performed by lowering the upper electrostatic chuck, and the interior of the process chamber should be maintained in a vacuum state during the bonding process.

However, checking whether or not the alignment between the upper target substrate and the lower target substrate is properly achieved before bonding is performed may be necessary. When an imaging camera is located inside the process chamber, the size of the process chamber increases, resulting in a longer time required to form a vacuum, and an alignment error between the upper target substrate and the lower target substrate may occur after bonding.

### SUMMARY

Embodiments of the present disclosure provide an electrostatic chuck having improved alignment accuracy.

Embodiments of the present disclosure provide a substrate treating apparatus including the electrostatic chuck.

Embodiments of the present disclosure provide a method of manufacturing a display device by using the substrate treating apparatus.

An electrostatic chuck, according to an embodiment, includes a body portion having a through hole, a cushion layer on the body portion and having a first inspection hole overlapping the through hole in a plan view, an electrode layer on the cushion layer and having a second inspection hole overlapping the first inspection hole in the plan view, and a dielectric layer on the electrode layer and having a surface exposed through the second inspection hole. At least a portion of the dielectric layer is transparent.

In an embodiment, the dielectric layer may include a transparent polyimide.

In an embodiment, the electrostatic chuck may further include a first insulating layer between the cushion layer and the electrode layer, a second insulating layer between the first insulation layer and the cushion layer, a first adhesive layer between the dielectric layer and the electrode layer, a second adhesive layer between the first insulating layer and the second insulating layer, and a third adhesive layer between the cushion layer and the second insulating layer.

In an embodiment, the through hole, the first inspection hole, and the second inspection hole may connect to each other and may extend from the body portion toward the surface of the dielectric layer.

In an embodiment, the electrostatic chuck may further include a transparent portion filling the through hole, the first inspection hole, and the second inspection hole, and contacting the surface of the dielectric layer. The transparent portion may penetrate the electrode layer, the cushion layer, the first insulating layer, the second insulating layer, the first adhesive layer, the second adhesive layer, and the third adhesive layer.

In an embodiment, the electrostatic chuck may further include a first buffer pad in a space between the transparent portion and an inner surface of the body portion and extending around a periphery of the transparent portion in the plane view, a first level adjuster under the transparent portion, a second level adjuster under the first level adjuster, and a third level adjuster under the second level adjuster and coupled to the second level adjuster and the body portion.

In an embodiment, the body portion may have a gas outlet, and the gas outlet may penetrate a portion of the body portion, may be connected to the space between the transparent portion and the inner surface of the body portion, and may extend toward an outer surface of the body portion.

In an embodiment, the through hole and the first inspection hole may connect to each other and may expose a surface of the second insulating layer. The second inspection hole may expose a surface of the first insulating layer.

In an embodiment, a third inspection hole may be formed in the second adhesive layer and may overlap the first inspection hole in the plan view.

In an embodiment, a first connecting hole may be formed in the first insulating layer and may connect the second inspection hole and the third inspection hole. A second connecting hole may be formed in the second insulating layer and may connect the first inspection hole and third inspection hole.

In an embodiment, a size of the first connecting hole may be less than a size of each of the second inspection hole and the third inspection hole. A size of the second connecting hole may be less than a size of each of the first inspection hole.

In an embodiment, the electrostatic chuck may include a transparent portion filling the through hole and the first inspection hole and may contact the surface of the second insulating layer. The transparent portion may penetrate the cushion layer and the second insulating layer.

A substrate treating apparatus, according to an embodiment, includes a process chamber having a space for processing a substrate, a first electrostatic chuck in the process chamber including a first dielectric layer configure to receive a first target substrate and a first body portion having a first through hole overlapping the first dielectric layer, a second electrostatic chuck in the process chamber configured to receive a second target substrate facing the first target substrate, and a first imaging part outside the process chamber and configured to receive a location data of the first target substrate by a first light irradiated toward the first electrostatic chuck.

In an embodiment, the first electrostatic chuck may include a first cushion layer on the first body portion and having a first inspection hole overlapping the first through hole in a plan view and a first electrode layer on the first cushion layer, overlapping the first inspection hole in the plan view and having a second inspection hole extending to a surface of the first dielectric layer. The first light may be irradiated toward the first through hole of the first electrostatic chuck, may pass through the first inspection hole and the second inspection hole, and may transmit through the first dielectric layer

In an embodiment, the second electrostatic chuck may include a second dielectric layer configured to receive the second target substrate is placed, at least a portion of the second dielectric layer being transparent, a second body portion having a second through hole overlapping the second dielectric layer in the plan view, a second cushion layer on the second body portion and having a third inspection hole overlapping the second through hole in the plan view, and a second electrode layer on the second cushion layer and having a fourth inspection hole overlapping the third inspection hole in the plan view and extending to a surface of the second dielectric layer.

In an embodiment, the substrate treating apparatus may further include a second imaging part outside the process chamber configured to receive a location data of the second target substrate by a second light configured to be irradiated toward the second electrostatic chuck. The second light may be irradiated toward the second through hole of the second electrostatic chuck and may pass through the third inspection hole and the fourth inspection hole and may transmit through the second dielectric layer.

A method of manufacturing a display device, according to an embodiment, includes placing a first target substrate on a first dielectric layer of a first electrostatic chuck in a process chamber, placing a second target substrate on a second dielectric layer of a second electrostatic chuck in the process chamber, forming a vacuum in a space inside the process chamber, irradiating a first light toward the first electrostatic chuck from outside the process chamber and receiving a first image data including a location data of a first region of interest at where an alignment mark of the first target substrate is arranged, determining whether or not the first target substrate is aligned based on the first image data, and when the first target substrate is determined to be aligned, coupling the first target substrate and the second target substrate together.

In an embodiment, in the receiving the first image data, the first light may be transmitted through the first electrostatic chuck and the first target substrate and may reach the second target substrate, and the first image data may further include a location data of a second region of interest at where an alignment mark of the second target substrate is arranged.

In an embodiment, the method may further include determining whether or not the second target substrate is aligned based on the first image data

In an embodiment, the method may further include irradiating a second light toward the second electrostatic chuck from outside the process chamber and receiving a second image data including a location data of a second region of interest at where an alignment mark of the second target substrate is arranged and determining whether or not the second target substrate is aligned based on the second image data.

In an electrostatic chuck, according to embodiments of the present disclosure, a dielectric layer on which the target substrate is placed may be transparent. Accordingly, when light is irradiated toward a through hole and an inspection hole from under the electrostatic chuck, recognition of an alignment mark disposed in the target substrate arranged on the dielectric layer may be possible. As a result, the accuracy and efficiency of inspection and alignment by using the electrostatic chuck may be improved.

In a substrate treating apparatus, according to embodiments of the present disclosure, because the dielectric layer on which the target substrate is placed is transparent, location measurement of the target substrates by imaging parts arranged outside the process chamber may be performed for each of the target substrates or may be performed concurrently (or simultaneously). Accordingly, a substrate treating apparatus having a structure that shortens process time and cost may be provided.

In a method of manufacturing a display device, according to embodiment of the present disclosure, by using the substrate treating apparatus, the time required to form a vacuum state may be relatively reduced, and because the positions of the target substrates may be determined after forming the vacuum state to align the target substrates, alignment errors between the target substrates may be prevented or reduced.

### BRIEF DESCRIPTION OF THE DRAWINGS

Illustrative, non-limiting embodiments of the present disclosure will be more clearly understood from the following detailed description in conjunction with the accompanying drawings, in which:

FIG. 1 is a perspective view of an electrostatic chuck according to an embodiment of the present disclosure.

FIG. 2 is a perspective cross-sectional view taken of a portion of the area A in the electrostatic chuck illustrated in FIG. 1.

FIG. 3 is a plan view of the electrostatic chuck and a target substrate shown in FIG. 2.

FIG. 4 is a plan view of the electrostatic chuck and the target substrate shown in FIG. 2 according to another embodiment.

FIG. 5 is a cross-sectional view of the area B1 in FIG. 2.

FIG. 6 is a schematic diagram of a first level adjuster, a second level adjuster, and a third level adjuster shown in FIG. 2.

FIG. 7 is a perspective cross-sectional view of the area A in the electrostatic chuck illustrated in FIG. 1 according to another embodiment.

FIG. 8 is a cross-sectional view of the area B2 in FIG. 7.

FIG. 9 is a perspective cross-sectional view of the area A of the electrostatic chuck illustrated in FIG. 1 according to another embodiment.

FIG. 10 is a plan view of the electrostatic chuck and the target substrate shown in FIG. 9.

FIG. 11 is a cross-sectional view of the area B3 in FIG. 9.

FIG. 12 is a perspective cross-sectional view of the area A of the electrostatic chuck illustrated in FIG. 1 according to another embodiment.

FIG. 13 is a cross-sectional view of the area B4 in FIG. 10.

FIG. 14 is a cross-sectional view of the area B4 in FIG. 10 according to another embodiment.

FIG. 15 is a perspective cross-sectional view of the area A of the electrostatic chuck illustrated in FIG. 1 according to another embodiment.

FIG. 16 is a cross-sectional of the area B5 in FIG. 15.

FIG. 17 is a cross-sectional view of the area B5 in FIG. 15 according to another embodiment.

FIG. 18 is a perspective cross-sectional view of the area A of the electrostatic chuck illustrated in FIG. 1 according to another embodiment.

FIG. 19 is a cross-sectional view of the area B6 in FIG. 18.

FIG. 20 is a cross-sectional view of the area B6 in FIG. 18 according to another embodiment.

FIG. 21 is a schematic diagram of a substrate treating apparatus including the electrostatic chuck shown in FIG. 1 according to an embodiment.

FIGS. 22 and 23 are diagrams illustrating a method for manufacturing a display device by using the substrate treating apparatus shown in FIG. 21.

FIG. 24 is a diagram illustrating a substrate treating apparatus including the electrostatic chuck shown in FIG. 1 according to another embodiment.

FIGS. 25, 26, and 27 are diagrams illustrating a method for manufacturing a display device by using the substrate treating apparatus shown in FIG. 24 according to various embodiments.

FIG. 28 is a schematic diagram of the target substrate shown in FIG. 1.

FIG. 29 is a cross-sectional view of the area C in FIG. 28.

FIG. 30 is a schematic diagram of an electronic device to which the display device of FIG. 28 is applied according to various embodiments.

### DETAILED DESCRIPTION

Hereinafter, display devices in accordance with embodiments will be described in more detail with reference to the accompanying drawings. The same reference numerals are used for the same components in the drawings, and redundant descriptions of the same components will be omitted.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

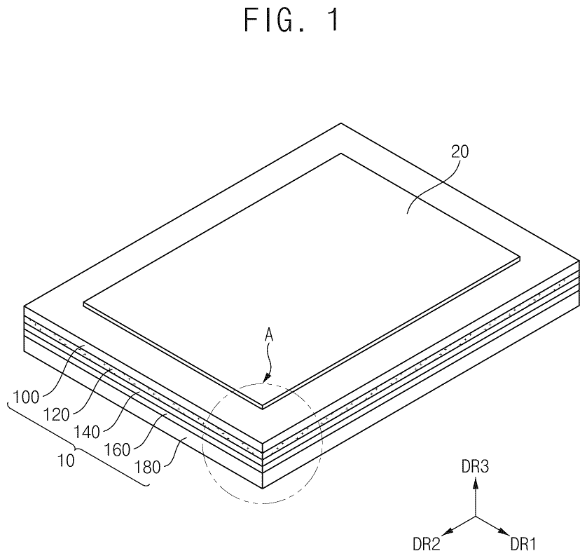

FIG. 1 is a perspective view of an electrostatic chuck according to an embodiment of the present disclosure.

Referring to FIG. 1, an electrostatic chuck 10, according to an embodiment of the present disclosure, may include a dielectric layer 100, an electrode layer 120, an insulating layer 140, a cushion layer 160, and a body portion 180. For example, on the body portion 180, the cushion layer 160, the insulating layer 140, the electrode layer 120, and the dielectric layer 100 may be sequentially stacked along a third direction DR3.

In the present disclosure, one plane may be defined in a first direction DR1 and a second direction DR2 crossing (e.g., intersecting) the first direction DR1. For example, the first direction DR1 may be perpendicular to the second direction DR2. In addition, the third direction DR3 may be perpendicular to the plane defined by the first direction DR1 and the second direction DR2.

Although the electrostatic chuck 10 shown in FIG. 1 is illustrated as having a rectangular planar shape, the electrostatic chuck 10 according to the embodiments of the present disclosure may not be limited thereto, and the planar shape of the electrostatic chuck 10 may be variously designed. For example, the electrostatic chuck 10 may have various planar shapes, such as a polygon, a circle, an ellipse, or a closed loop.

In an embodiment, a target substrate 20 may be placed on the electrostatic chuck 10. For example, the target substrate 20 may be placed on the dielectric layer 100. In an embodiment, the target substrate 20, as an object to be adsorbed, may be adsorbed on the electrostatic chuck 10 by an electrostatic force.

The target substrate 20 may be placed on the dielectric layer 100. In an embodiment, at least a portion of the dielectric layer 100 may be transparent. For example, for inspection or alignment of the dielectric layer 100, a portion through which light is transmitted when the target substrate 20 is placed may be transparent.

In an embodiment, the dielectric layer 100 may include a transparent material. For example, the dielectric layer 100 may include a transparent polymer material, such as transparent polyimide PI.

The electrode layer 120 may be arranged under the dielectric layer 100. In an embodiment, the electrode layer 120 may include a conductive material. For example, the conductive material may include copper (Cu), aluminum (Al), gold (Au), silver (Ag), platinum (Pt), titanium (Ti), tungsten (W), molybdenum (Mo), carbon nanotube (CNT), conductive polymer, and transparent conductive oxide (TCO). These may be used alone or in combination.

The insulating layer 140 may be arranged under the electrode layer 120. In an embodiment, the insulating layer 140 may include a polymer material, such as polyimide PI. In an embodiment, the insulating layer 140 may include a transparent polymer material. The insulating layer 140 may reduce or prevent damage to the electrode layer 120 caused by pressure generated while the target substrate 20 is pressed on the electrostatic chuck 10. In an embodiment, the insulating layer 140 may have a multi-layer structure. However, the insulating layer 140 according to the embodiments of the present disclosure may not be limited thereto, and the insulating layer 140 may have a single-layer structure.

The cushion layer 160 may be arranged under the insulating layer 140. In an embodiment, the cushion layer 160 may include a polymer material. In an embodiment, the thickness of the cushion layer 160 may be greater than the thickness of the dielectric layer 100. Accordingly, because the cushion layer 160 may be deformed by the pressure from the target substrate 20, damage to the target substrate 20 due to the pressure may be reduced or prevented.

The body portion 180 may be arranged under the cushion layer 160. The body portion 180 may form a frame of the electrostatic chuck 10. For example, the body portion 180 may support the dielectric layer 100, the electrode layer 120, the insulating layer 140, and the cushion layer 160. In an embodiment, the body portion 180 may include a metal material. For example, the metal material may include aluminum (Al), iron (Fe), copper (Cu), and stainless steel. These may be used alone or in combination.

In an embodiment, the body portion 180 may include a light-absorbing material. For example, the body portion 180 may include a core of the metal material and an oxide film having a relatively high light absorbance, such as black anodizing, coated on the surface of the metal material. Accordingly, by absorbing light irradiated to an area other than an area for checking the location of the target substrate 20, the efficiency of the alignment process by using the electrostatic chuck 10 and the alignment accuracy of the target substrate 20 may be improved.

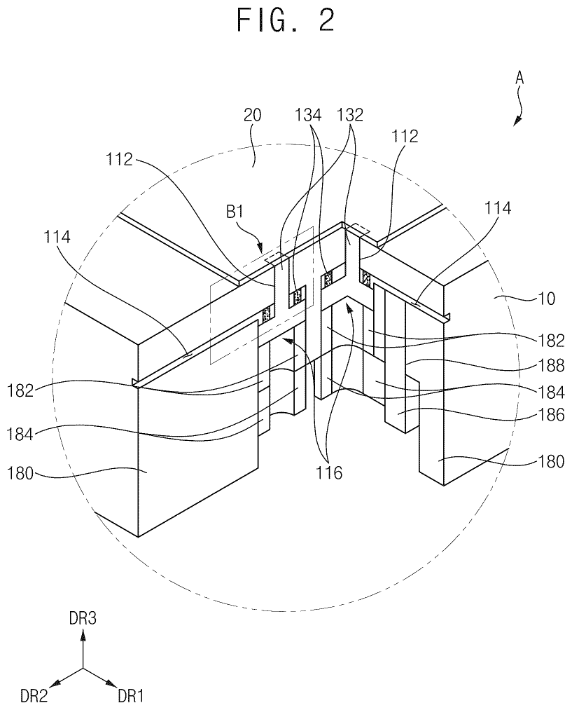

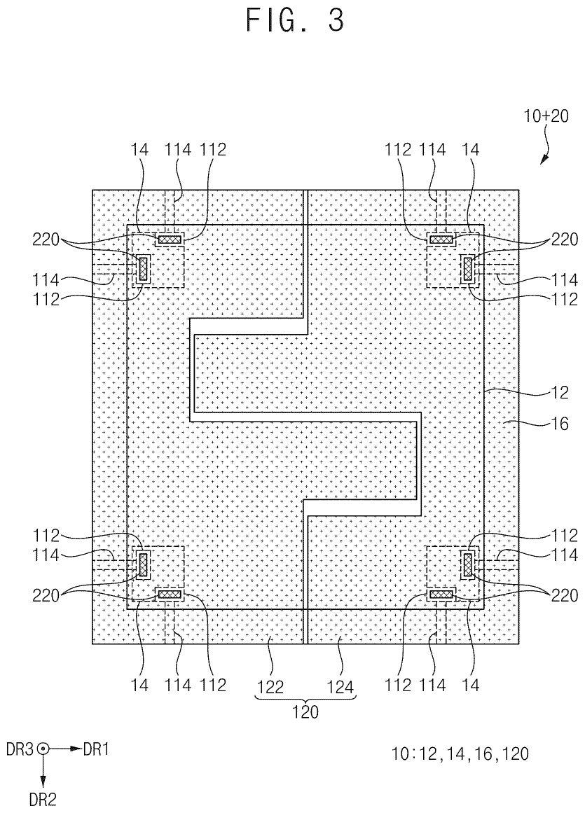

FIG. 2 is a perspective cross-sectional view of the area A of the electrostatic chuck illustrated in FIG. 1. FIG. 3 is a plan view of the electrostatic chuck and a target substrate shown in FIG. 2.

Referring to FIGS. 1, 2, and 3, the electrostatic chuck 10 may include an adsorption area 12, an inspection area 14, and a surrounding area (e.g., a peripheral area) 16. Each of the adsorption area 12, the inspection area 14, and the surrounding area 16 may be an area partitioned to describe placing and alignment of the target substrate 20 by using the electrostatic chuck 10.

The adsorption area 12 may be an area in which the target substrate 20 is placed on the electrostatic chuck 10. Although the adsorption area 12 is illustrated as having a rectangular planar shape in FIG. 3, the adsorption area 12 according to the embodiments of the present disclosure may not be limited thereto, and the size and shape of the adsorption area 12 may be variously changed to correspond to the size and shape of the object to be adsorbed. For example, when the target substrate 20 as the object to be adsorbed has corners with a rounded shape, corners of the adsorption area 12 may also have a rounded shape.

In the present disclosure, the corners of the adsorption area 12 may be defined by two sides of the adsorption area 12 meeting each other in a plan view.

The inspection area 14 may be an area in which (or which) a light source is irradiated and an image is captured by a camera. For example, location information regarding the electrostatic chuck 10 and the target substrate 20 located in the inspection area 14 may be obtained through (e.g., by using) the light source and the camera, and whether or not the target substrate 20 is accurately placed at a specific location on the electrostatic chuck 10 may be checked (or determined).

In an embodiment, the inspection area 14 may overlap the adsorption area 12 in a plan view. In an embodiment, the inspection area 14 may be located within the adsorption area 12. For example, the inspection area 14 may be located at a corner of the adsorption area 12. However, the relationship between the adsorption area 12 and the inspection area 14 according to the embodiments of the present disclosure may not be limited thereto, and at least a portion of the inspection area 14 may overlap the surrounding area 16 in a plan view.

The surrounding area 16 may be adjacent to the adsorption area 12. For example, the surrounding area 16 may surround at least a portion of the adsorption area 12. In an embodiment, the surrounding area 16 may not overlap the target substrate 20 in a plan view. For example, the surrounding area 16 may be an area in which the target substrate 20 is not placed.

An inspection hole (e.g., an inspection opening) 112, a gas outlet 114, and a through hole 116 may be formed in the electrostatic chuck 10. The electrostatic chuck 10 may further include transparent portions 132, a buffer pad 134, a first level adjuster 182, a second level adjuster 184, and a third level adjuster 186. In addition, the electrode layer 120 included in the electrostatic chuck 10 may include a first electrode 122 and a second electrode 124.

In an embodiment, the inspection hole 112 may penetrate at least a portion of an upper portion of the electrostatic chuck 10 in a thickness direction (e.g., the third direction DR3). For example, in the inspection area 14, the inspection hole 112 may penetrate the electrode layer 120 in a thickness direction (e.g., the third direction DR3). In an embodiment, the inspection hole 112 may extend to the upper surface of the electrostatic chuck 10.

In an embodiment, the inspection hole 112 may be located at a corner of the adsorption area 12. For example, the inspection hole 112 may be located within the inspection area 14. In an embodiment, two inspection holes 112 may be arranged at one corner of the inspection area 14. However, the arrangement and number of inspection hole 112 according to the embodiments of the present disclosure may not be limited thereto.

The gas outlet 114 may extend toward a side surface of the electrostatic chuck 10. For example, the gas outlet 114 may be connected to the inspection hole 112 and may extend toward the side surface of the electrostatic chuck 10 along a direction parallel to the first direction DR1 or a direction parallel to the second direction DR2. For example, within one inspection area 14, one gas outlet 114 may extend along a direction parallel to the first direction DR1, and the other gas outlet 114 may extend along a direction parallel to the second direction DR2. In an embodiment, the gas outlet 114 may extend from the adsorption area 12 toward the surrounding area 16.

In an embodiment, in one inspection area 14, the number of the inspection holes 112 and the number of the gas outlets 114 may be the same. In an embodiment, when two inspection holes 112 are arranged at one corner of the adsorption area 12, two gas outlets 114 may also be arranged at the same corner of the adsorption area 12. However, the arrangement and number of the gas outlet 114 according to the embodiments of the present disclosure may not be limited thereto.

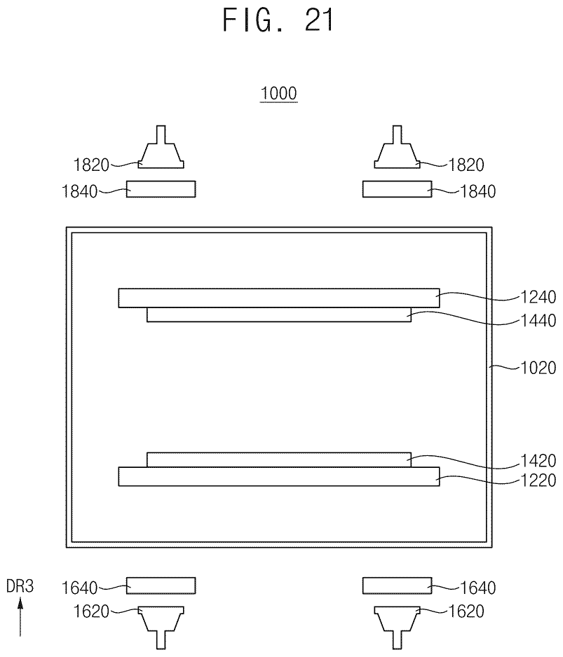

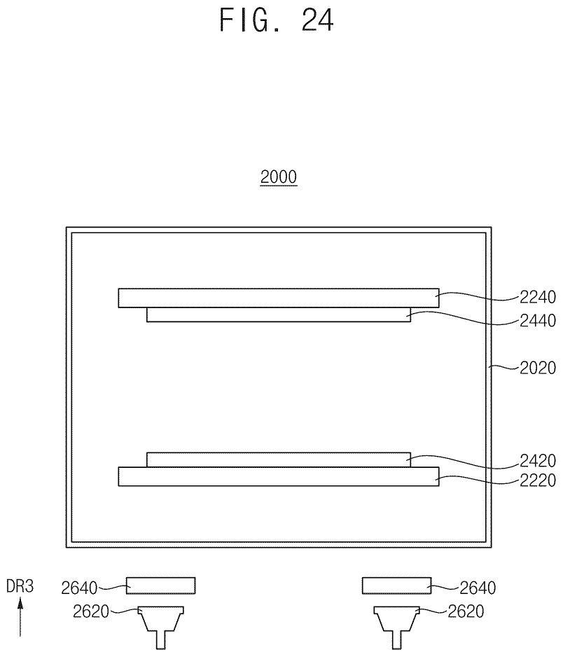

The gas outlet 114 may prevent gas (e.g., air) from being trapped inside the electrostatic chuck 10. For example, when a vacuum state is formed in a process chamber (e.g., the process chamber 1020 shown in FIG. 21 or the process chamber 2020 shown in FIG. 24) to adsorb the target substrate 20 onto the electrostatic chuck 10, the gas outlet 114 may act as a passage for discharging residual gas remaining inside the electrostatic chuck 10. Accordingly, damage or defects to internal components of the electrostatic chuck 10 caused by gas trapped inside of the electrostatic chuck 10 may be prevented.

The through hole 116 may penetrate at least a portion of the body portion 180 in a thickness direction (e.g., the third direction DR3). In an embodiment, the through hole 116 may overlap the inspection hole 112 in a plan view. In an embodiment, in a plan view, the size of the through hole 116 may be larger than the size of the inspection hole 112. However, the size relationship between the inspection hole 112 and the through hole 116 according to the embodiments of the present disclosure may not be limited thereto.

In an embodiment, in one inspection area 14, the number of the inspection holes 112 and the number of the through holes 116 may be the same. In an embodiment, when two inspection holes 112 are arranged at one corner of the adsorption area 12, two through holes 116 may also be arranged at the same corner of the adsorption area 12. However, the arrangement and number of through hole 116 according to the embodiments of the present disclosure may not be limited thereto.

In an embodiment, at least a portion of the through hole 116 may be located in the inspection area 14. The inspection hole 112 and the through hole 116 may be holes (e.g., openings) formed to allow light irradiated from a lower surface of the electrostatic chuck 10 (e.g., the other surface opposite to the one surface on which the target substrate 20 is placed) to be transmitted therethrough. For example, the light emitted from the illumination may sequentially pass through the through hole 116 and the transparent portion 132 disposed in the inspection hole 112.

However, the shapes, sizes, and arrangements of the inspection hole 112, the gas outlet 114, and the through hole 116 in a plan view according to the embodiments of the present disclosure may not be limited thereto, and the shapes, sizes, and arrangements of the inspection hole 112, the gas outlet 114, and the through hole 116 may be various. In addition, the extending direction of the gas outlet 114 according to the embodiments of the present disclosure may not be limited thereto.

The transparent portion 132 may fill the inspection hole 112 in a plan view. For example, a first portion of the transparent portion 132 may fill the inspection hole 112, and a second portion of the transparent portion 132 may fill a portion of the through hole 116 penetrating the body portion 180. In an embodiment, the transparent portion 132 may have a shape in which an upper portion (e.g., the first portion) is less in size than a lower portion (e.g., the second portion). For example, the size of the first portion of the transparent portion 132 may be constant along the third direction DR3, and the size of the second portion of the transparent portion 132 may also be constant along the third direction DR3. However, the shape of the transparent portion 132 according to the embodiments of the present disclosure may not be limited thereto.

In an embodiment, the transparent portion 132 may include a transparent material. For example, the transparent portion 132 may include quartz, glass, or silicone. These may be used alone or in combination. In an embodiment, the transparent portion 132 may have a light transmittance of about 90% or more. In some embodiments, the transparent portion 132 may have a light transmittance in a range of about 95% to about 99.999%.

In an embodiment, at least a portion of the transparent portion 132 may be anti-reflection coated. In an embodiment, an upper surface of the transparent portion 132 (e.g., one surface of the transparent portion 132 facing the target substrate 20) may be an anti-reflection coated surface. In an embodiment, a lower surface of the transparent portion 132 (e.g., the other surface of the transparent portion 132 opposite to the one surface facing the target substrate 20) may be an anti-reflection coated surface.

When two inspection holes 112 are arranged at one corner of the adsorption area 12, two transparent portions 132 may also be arranged at the same corner of the adsorption area 12. However, the arrangement and number of transparent portions 132 according to the embodiments of the present disclosure may not be limited thereto.

The buffer pad 134 may be arranged in a space between an upper portion of the electrostatic chuck 10 and the transparent portion 132. For example, the upper portion of the electrostatic chuck 10 may be spaced apart from an inner surface of the body portion 180. Accordingly, the buffer pad 134 may be arranged in a space formed by the upper portion of the electrostatic chuck 10 and the inner surface of the body portion 180 being spaced apart from each other. In an embodiment, the gas outlet 114 may extend toward an outer surface of the body portion 180 from the space between the upper portion and the inner surface of the body portion 180.

In an embodiment, the buffer pad 134 may surround (e.g., may extend around a periphery of) at least a portion of the transparent portion 132. For example, the buffer pad 134 may surround (e.g., may extend around a periphery of) the transparent portion 132 while maintaining a constant distance therefrom. Accordingly, the buffer pad 134 may prevent the transparent portion 132 from shaking (or vibrating) as the gas is discharged through the gas outlet 114 in the vacuum state. For example, the buffer pad 134 may act as a pre-load that fixes the transparent portion 132 in the vacuum state while preventing wear of the transparent portion 132.

In an embodiment, the buffer pad 134 may be a silicone pad formed by curing silicone resin. However, the type of the buffer pad 134 according to the embodiments of the present disclosure may not be limited thereto, and the buffer pad 134 may also be a urethane pad, a polyurethane pad, or a rubber pad.

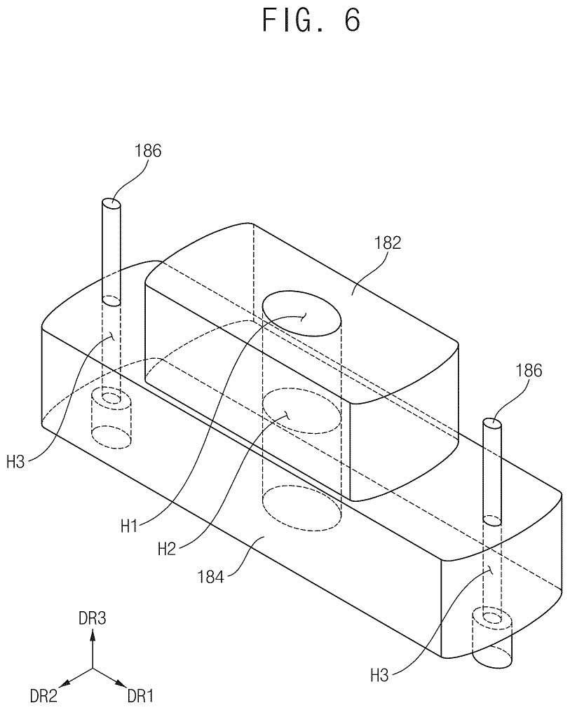

The first level adjuster 182 may be arranged under the transparent portion 132. In an embodiment, the first level adjuster 182 may be disposed within the through hole 116. A first hole (e.g., the first hole H1 shown in FIG. 6) for exposing a lower surface of the transparent portion 132 may be formed in the first level adjuster 182. In an embodiment, the size of the first hole of the first level adjuster 182 may be substantially the same as the size of the inspection hole 112. However, the size of the first hole according to the embodiments of the present disclosure may not be limited thereto. In an embodiment, the first level adjuster 182 may be a leveling nut for adjusting a level (e.g., height) of the transparent portion 132.

The second level adjuster 184 may be arranged under the first level adjuster 182. In an embodiment, the second level adjuster 184 may be located within the through hole 116 in a plan view. A second hole (e.g., the second hole H2 shown in FIG. 6) for exposing the lower surface of the transparent portion 132 may be formed in the second level adjuster 184. For example, the first hole and the second hole may be connected to each other and extend toward the lower surface of the transparent portion 132. In an embodiment, the size of the second hole of the second level adjuster 184 may be substantially the same as the size of the inspection hole 112. However, the size of the second hole according to the embodiments of the present disclosure may not be limited thereto. In an embodiment, the second level adjuster 184 may be a nut for fixing the location of the first level adjuster 182.

The third level adjuster 186 may fix the locations of the first level adjuster 182 and the second level adjuster 184. The third level adjuster 186 may be coupled to the body portion 180 and the second level adjuster 184 at the same time. For example, the third level adjuster 186 may be coupled to a fixing hole 188 penetrating at least a portion of the body portion 180 and to a hole penetrating the second level adjuster 184. In an embodiment, the third level adjuster 186 may have a protruding shape. For example, the third level adjuster 186 may be a bolt.

Because the third level adjuster 186 is coupled to the body portion 180 through the fixing hole 188 to fix the location of the second level adjuster 184, the levels of the first level adjuster 182 and the second level adjuster 184 may be adjusted by using the third level adjuster 186. For example, by using the third level adjuster 186, a constant gap may be formed between the first level adjuster 182 and the second level adjuster 184, or the second level adjuster 184 may be brought into close contact with the first level adjuster 182 so that no gap is formed between the first level adjuster 182 and the second level adjuster 184. Accordingly, the levels of each of the transparent portion 132, the buffer pad 134, the first level adjuster 182, and the second level adjuster 184 may be easily adjusted.

A first voltage may be applied to the first electrode 122. A second voltage different from the first voltage may be applied to the second electrode 124. For example, the first voltage may be a positive voltage, and the second voltage may be a negative voltage. In another example, the first voltage may be a negative voltage, and the second voltage may be a positive voltage. In an embodiment, the first electrode 122 may include a first terminal to which the first voltage is supplied from the outside, and the second electrode 124 may include a second terminal to which the second voltage is supplied from the outside.

In an embodiment, the first electrode 122 and the second electrode 124 may be spaced apart from each other in a plan view. For example, the first electrode 122 may be arranged on one side of the second electrode 124, and the first electrode 122 and the second electrode 124 may be electrically separated from each other. Accordingly, due to the voltage applied to the electrode layer 120, the target substrate 20 may be adsorbed on the dielectric layer 100 by the electrostatic force. However, the shape, size, and arrangement relationship of the first electrode 122 and the second electrode 124 according to the embodiments of the present disclosure may not be limited thereto. For example, the second electrode 124 may surround the first electrode 122 in a plan view.

The target substrate 20 may include an alignment mark 220. The target substrate 20 may be arranged at a specific location on the electrostatic chuck 10 through the alignment mark 220. For example, the alignment mark 220 may be an alignment key. In an embodiment, the alignment mark 220 may be arranged at a corner of the target substrate 20. For example, at least one alignment mark 220 may be arranged at each of four corners of the target substrate 20. However, shape, size, and arrangement of the alignment mark 220 according to the embodiments of the present disclosure may not be limited thereto.

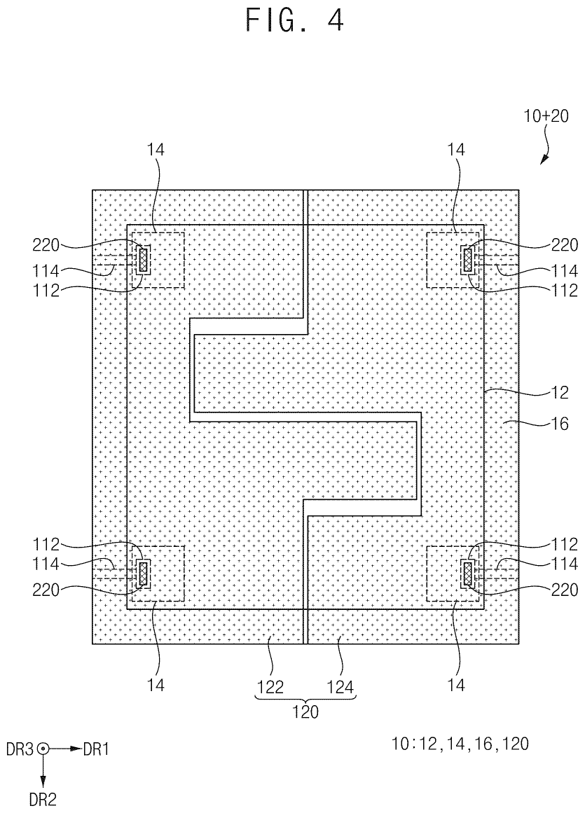

FIG. 4 is a plan view of the electrostatic chuck and the target substrate shown in FIG. 2 according to another embodiment.

The electrostatic chuck 10 and the target substrate 20 shown in FIG. 4 may be substantially the same as or similar to the electrostatic chuck 10 and the target substrate 20 shown in FIG. 3, except for the number and locations of the inspection hole 112, the gas outlet 114, and the alignment mark 220. Hereinafter, overlapping content with the description referring to FIGS. 1, 2, and 3 may be omitted or only briefly provided.

Referring to FIG. 4, one inspection hole 112 and one gas outlet 114 may be formed in one inspection area 14 of the electrostatic chuck 10. For example, one inspection hole 112 and one gas outlet 114 may be located at one corner of the electrostatic chuck 10.

In an embodiment, the gas outlet 114 may extend in a direction parallel to the first direction DR1 from one side of the inspection hole 112. However, the extending direction of the gas outlet 114 according to the embodiments of the present disclosure may not be limited thereto. For example, the gas outlet 114 may extend in a direction parallel to the second direction DR2 from one side of the inspection hole 112.

Because one inspection hole 112 is formed in one inspection area 14 of the electrostatic chuck 10, one alignment mark 220 may be arranged in one inspection area 14. For example, because the alignment mark 220 is arranged corresponding to the location of the inspection hole 112, one alignment mark 220 may be arranged at one corner of the electrostatic chuck 10. However, the arrangement and number of the inspection hole 112, the gas outlet 114, and the alignment mark 220 according to the embodiments of the present disclosure may not be limited thereto.

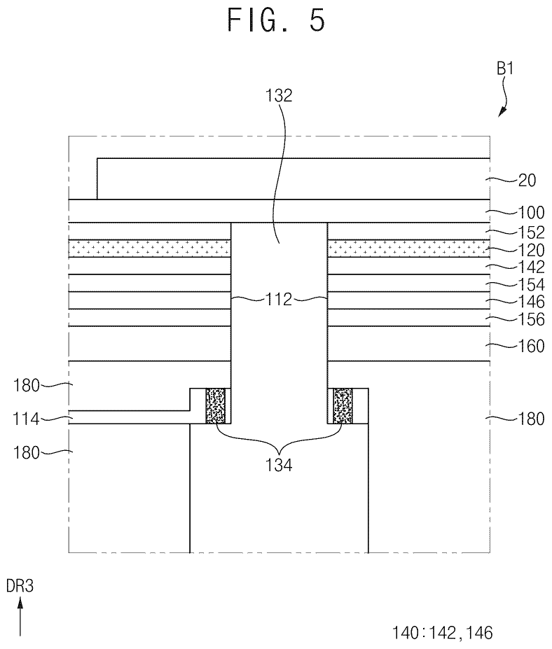

FIG. 5 is a cross-sectional view of the area B1 in FIG. 2. FIG. 5 is a cross-sectional view of the electrostatic chuck 10 and the target substrate 20 adjacent to the inspection hole 112.

Referring to FIGS. 1, 2, and 5, the insulating layer 140 may include a first insulating layer 142 and a second insulating layer 146. The electrostatic chuck 10 may further include a first adhesive layer 152, a second adhesive layer 154, and a third adhesive layer 156.

In an embodiment, the third adhesive layer 156, the second insulating layer 146, the second adhesive layer 154, the first insulating layer 142, the electrode layer 120, the first adhesive layer 152, and the dielectric layer 100 may be sequentially stacked on the cushion layer 160 along the third direction DR3.

In an embodiment, the inspection hole 112 may penetrate the dielectric layer 100, the first adhesive layer 152, the electrode layer 120, the first insulating layer 142, the second adhesive layer 154, the second insulating layer 146, the third adhesive layer 156, the cushion layer 160, and the body portion 180 in the third direction DR3. In an embodiment, the transparent portion 132 may fill the inspection hole 112 and may directly contact the inner surfaces of the dielectric layer 100, the first adhesive layer 152, the electrode layer 120, the first insulating layer 142, the second adhesive layer 154, the second insulating layer 146, the third adhesive layer 156, the cushion layer 160, and the body portion 180 defined by the inspection hole 112.

The first insulating layer 142 may be arranged under the electrode layer 120. The second insulating layer 146 may be arranged under the first insulating layer 142. In an embodiment, the first insulating layer 142 may include a polymer material, such as polyimide. In an embodiment, the second insulating layer 146 may include a polymer material, such as polyimide.

In an embodiment, the first insulating layer 142 and the second insulating layer 146 may include the same material. For example, the first insulating layer 142 and the second insulating layer 146 may include polyimide. However, materials included in each of the first insulating layer 142 and the second insulating layer 146 according to the embodiments of the present disclosure may not be limited thereto, and the first insulating layer 142 and the second insulating layer 146 may include different materials from each other.

In an embodiment, the dielectric layer 100 and the first insulating layer 142 may include different materials. For example, the dielectric layer 100 may include a transparent material (e.g., transparent polyimide), and the first insulating layer 142 may not include a transparent material. In another embodiment, the dielectric layer 100 and the first insulating layer 142 may include the same material. For example, the dielectric layer 100 and the first insulating layer 142 may both include a transparent material.

In an embodiment, the dielectric layer 100 and the second insulating layer 146 may include different materials. For example, the dielectric layer 100 may include a transparent material (e.g., transparent polyimide), and the second insulating layer 146 may not include a transparent material. In another embodiment, the dielectric layer 100 and the second insulating layer 146 may include the same material. For example, the dielectric layer 100 and the second insulating layer 146 may both include a transparent material.

The first adhesive layer 152 may be arranged between the dielectric layer 100 and the electrode layer 120. For example, the first adhesive layer 152 may couple the dielectric layer 100 and the electrode layer 120 between the dielectric layer 100 and the electrode layer 120. In an embodiment, the first adhesive layer 152 may include a non-transparent adhesive. In another embodiment, the first adhesive layer 152 may include a transparent adhesive.

The second adhesive layer 154 may be arranged between the first insulating layer 142 and the second insulating layer 146. For example, the second adhesive layer 154 may couple the first insulating layer 142 and the second insulating layer 146 between the first insulating layer 142 and the second insulating layer 146. In an embodiment, the second adhesive layer 154 may include a non-transparent adhesive. In another embodiment, the second adhesive layer 154 may include a transparent adhesive.

The third adhesive layer 156 may be arranged between the second insulating layer 146 and the cushion layer 160. For example, the third adhesive layer 156 may couple the second insulating layer 146 and the cushion layer 160 between the second insulating layer 146 and the cushion layer 160. In an embodiment, the third adhesive layer 156 may include a non-transparent adhesive. In another embodiment, the third adhesive layer 156 may include a transparent adhesive.

FIG. 6 is a schematic diagram of a first level adjuster, a second level adjuster, and a third level adjuster shown in FIG. 2.

Referring to FIGS. 2 and 6, the first level adjuster 182 and the second level adjuster 184 may be arranged under the transparent portion 132. In an embodiment, a first hole H1 and a second hole H2 exposing the lower surface of the transparent portion 132 may be respectively formed in the first level adjuster 182 and the second level adjuster 184, and the first hole H1 and the second hole H2 may be paths through which light introduced from under the second level adjuster 184 travels.

In an embodiment, in a plan view, a size of the second level adjuster 184 may be greater than a size of the first level adjuster 182. Accordingly, in a plan view, the first level adjuster 182 may overlap a portion of an upper surface of the second level adjuster 184.

In an embodiment, a third hole H3 coupled to a third level adjuster 186 may be formed in the second level adjuster 184. For example, the third level adjuster 186 may rotate clockwise or counterclockwise to fully fill the third hole H3 and to be coupled to the second level adjuster 184. The third level adjuster 186 may rotate clockwise or counterclockwise to fill the fixing hole 188 and may be coupled to the body portion 180. For example, the third level adjuster 186 may fill the entire fixing hole 188 or a portion of the fixing hole 188. For example, depending on the rotation of the third level adjuster 186, the third level adjuster 186 may fill the third hole H3 of the second level adjuster 184 and the fixing hole 188 along the third direction DR3.

The levels of the first level adjuster 182 and the second level adjuster 184 may be adjusted according to the depth to which the third level adjuster 186 fills the fixing hole 188. For example, when the third level adjuster 186 partially fills the fixing hole 188, a gap may be generated between the first level adjuster 182 and the second level adjuster 184. For example, when the third level adjuster 186 fully fills the fixing hole 188, the first level adjuster 182 and the second level adjuster 184 may be in close contact with each other such that no gap may be formed between the first level adjuster 182 and the second level adjuster 184. For example, the levels of the first level adjuster 182 and the second level adjuster 184 may be adjusted according to a degree of rotation of the third level adjuster 186 and the coupling depth with the body portion 180.

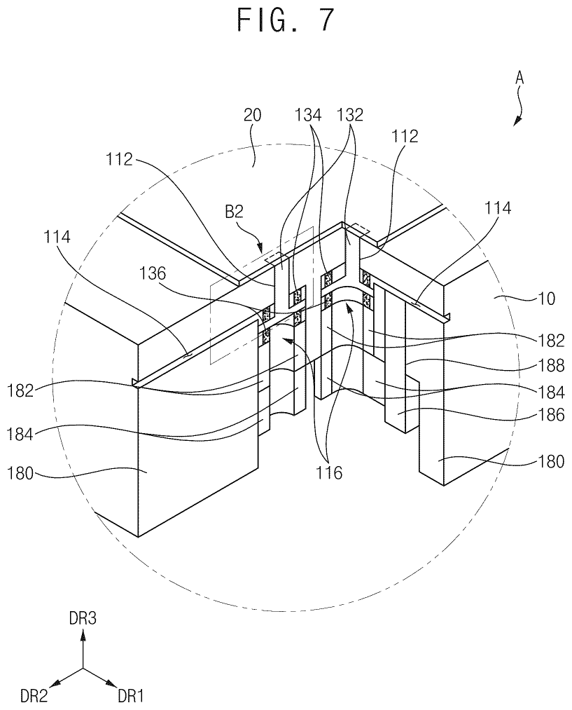

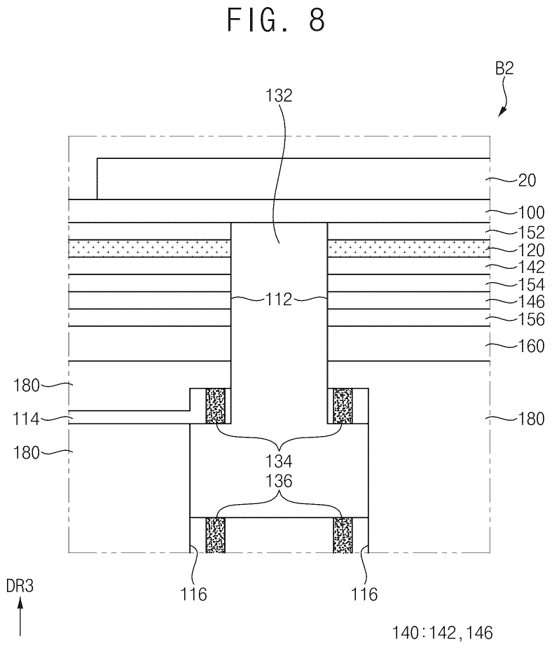

FIG. 7 is a perspective cross-sectional view n of the area A of the electrostatic chuck illustrated in FIG. 1 according to another embodiment. FIG. 8 is a cross-sectional view of the area B2 in FIG. 7. For example, FIG. 8 is a cross-sectional view illustrating the electrostatic chuck 10 and the target substrate 20 adjacent to the inspection hole 112.

A structure of the electrostatic chuck 10 with reference to FIGS. 7 and 8 may be substantially the same as or similar to the structure of the electrostatic chuck 10 described with reference to FIGS. 2 and 5, except that a second buffer pad 136 is further arranged. Hereinafter, overlapping descriptions with those described with reference to FIGS. 2 and 5 may be omitted or briefly described.

Referring to FIGS. 1, 7, and 8, in an embodiment, the electrostatic chuck 10 may include a first buffer pad 134 and a second buffer pad 136 surrounding (e.g., extending around a periphery of) at least a portion of the transparent portion 132. In an embodiment, the first buffer pad 134 may surround, in a plan view, a first portion, that is, an upper portion, of the transparent portion 132. In an embodiment, the first buffer pad 134 may be arranged on a second portion, that is, a lower portion, of the transparent portion 132. For example, the first buffer pad 134 may be adjacent to a side of the transparent portion 132 at where the first portion of the transparent portion 132 is connected to the second portion of the transparent portion 132.

In an embodiment, the first buffer pad 134 may be arranged in a space between the first portion of the transparent portion 132 and the body portion 180. In an embodiment, the first buffer pad 134 may not overlap (e.g., may be offset from) the inspection hole 112 in a plan view. In an embodiment, the first buffer pad 134 may be arranged in the through hole 116 in a plan view.

In an embodiment, the second buffer pad 136 may be arranged on the first level adjuster 182. In an embodiment, the second buffer pad 136 may not overlap (e.g., may be offset from) the inspection hole 112 in a plan view. In an embodiment, the second buffer pad 136 may be arranged in the through hole 116 in a plan view.

In an embodiment, the second buffer pad 136 may overlap the first buffer pad 134 in a plan view. For example, the first buffer pad 134 and the second buffer pad 136 may be arranged at the same location in a plan view. However, the arrangement of the first buffer pad 134 and the second buffer pad 136 according to the embodiments of the present disclosure may not be limited thereto.

In an embodiment, the first buffer pad 134 may be arranged on an upper side of the second portion of the transparent portion 132, and the second buffer pad 136 may be arranged under the second portion of the transparent portion 132. For example, in a cross-sectional view, the first buffer pad 134 may be arranged between the second portion of the transparent portion 132 and the body portion 180. For example, in a cross-sectional view, the second buffer pad 136 may be arranged between the transparent portion 132 and the first level adjuster 182.

As described above, because the electrostatic chuck 10 includes the first buffer pad 134 surrounding the first portion of the transparent portion 132 and the second buffer pad 136 arranged under the second portion of the transparent portion 132, a phenomenon in which the transparent portion 132 shakes (or vibrates) or a phenomenon in which the transparent portion 132 is damaged in a vacuum state may be prevented.

The length of the second portion of the transparent portion 132 in the third direction DR3 shown in FIG. 8 may be less than the length in the third direction DR3 of the second portion of the transparent portion 132 shown in FIG. 5. For example, as the second buffer pad 136 is arranged under the second portion of the transparent portion 132, the length in the third direction DR3 of the second portion of the transparent portion 132 may be relatively reduced.

In an embodiment, the first buffer pad 134 and the second buffer pad 136 may include the same material. For example, the first buffer pad 134 and the second buffer pad 136 may include a silicon pad. However, the materials included in each of the first buffer pad 134 and the second buffer pad 136 according to the embodiments of the present disclosure may not be limited thereto, and the first buffer pad 134 and the second buffer pad 136 may include different materials from each other.

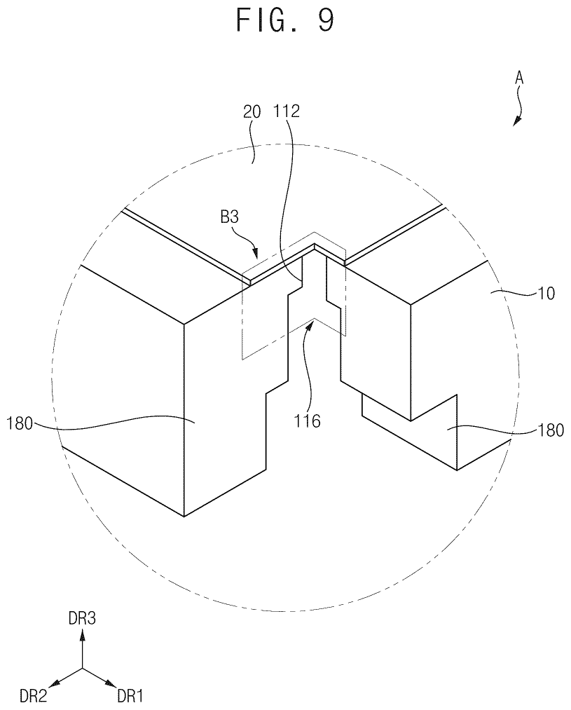

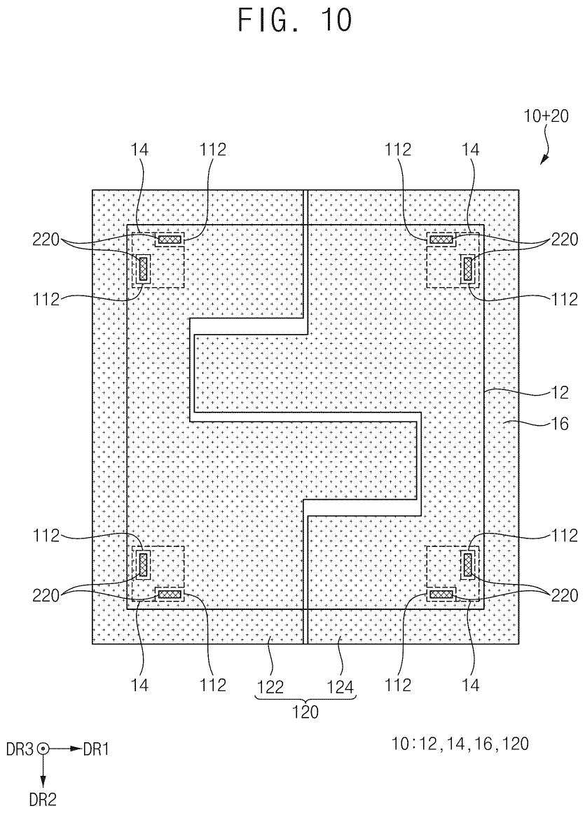

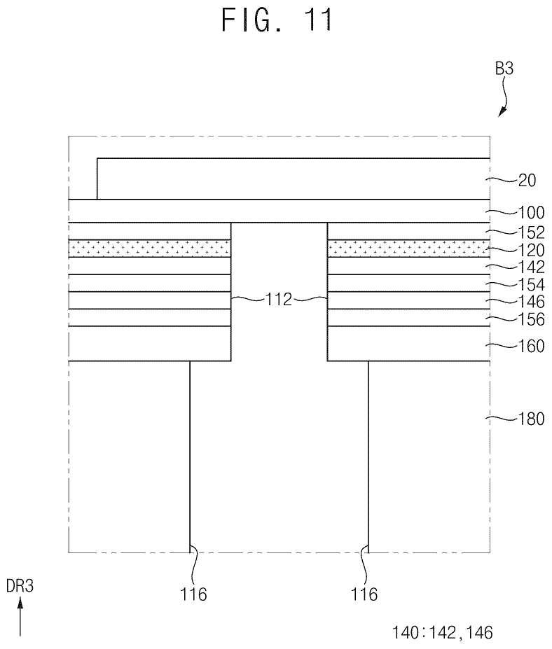

FIG. 9 is a perspective cross-sectional view of the area A of the electrostatic chuck illustrated in FIG. 1 according to another embodiment. FIG. 10 is a plan view illustrating the electrostatic chuck and the target substrate shown in FIG. 9. FIG. 11 is a cross-sectional view of the area B3 in FIG. 9. For example, FIG. 11 is a cross-sectional view of the electrostatic chuck 10 and the target substrate 20 adjacent to the inspection hole 112.

A structure of the electrostatic chuck 10 with reference to FIGS. 9, 10, and 11 may be substantially the same as or similar to the structure of the electrostatic chuck 10 described with reference to FIGS. 2, 3, and 5, except that a configuration filling the inspection hole 112 and the through hole 116 is not arranged, and an outlet for gas discharge is not formed. Hereinafter, overlapping descriptions with those described with reference to FIGS. 2, 3, and 5 may be omitted or briefly described.

Referring to FIGS. 1 and 9, 10, and 11, in an embodiment, an inspection hole 112 penetrating at least a portion of the electrostatic chuck 10 in a thickness direction (e.g., the third direction DR3) and a through hole 116 connected to (e.g., in fluid communication with) the inspection hole 112 may be formed. The inspection hole 112 and the through hole 116 may be connected to expose a lower surface of the dielectric layer 100. In other words, a member or structure (e.g., the transparent portion 132 of FIG. 2) filling the inspection hole 112 and the through hole 116 may not be arranged (or may not be present).

Specifically, because the member or the structure filling the inspection hole 112 is not arranged, fixing elements or fastening elements, such as bolts and nuts, for adjusting the level of the member or the structure or for supporting the member or the structure may not be arranged (or may be omitted). Accordingly, because the member or the structure having a relatively high light transmittance is not arranged, the manufacturing cost and time of the electrostatic chuck 10 may be reduced, and a relatively cost-efficient and simplified structure of the electrostatic chuck 10 may be provided.

In an embodiment, an outlet for gas discharge (e.g., the gas outlet 114 shown in FIG. 2) may not be formed on a side surface of the electrostatic chuck 10. In other words, a hole extending from the inspection hole 112 toward the side surface of the electrostatic chuck 10 may not be formed.

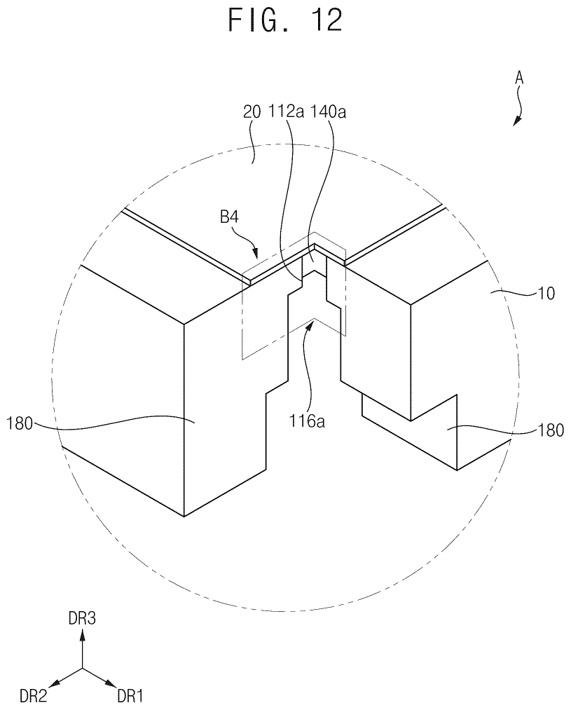

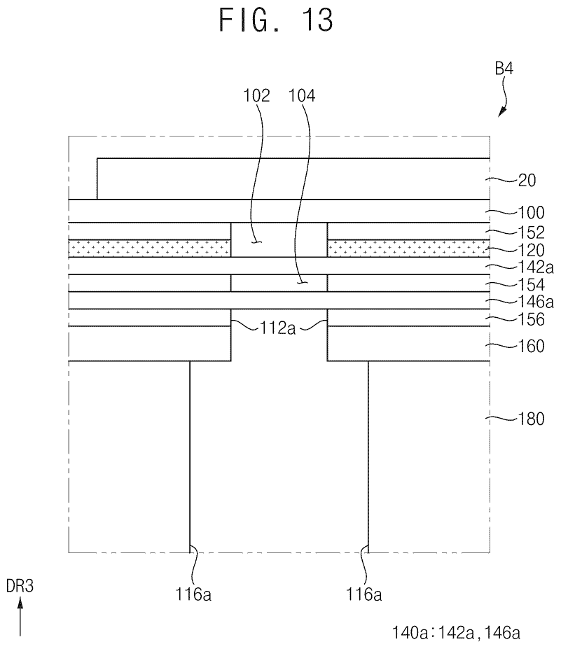

FIG. 12 is a perspective cross-sectional view of the area A of the electrostatic chuck illustrated in FIG. 1 according to another embodiment. FIG. 13 is a cross-sectional view of the area B4 in FIG. 10. FIG. 13 is a cross-sectional view of the electrostatic chuck 10 and the target substrate 20 adjacent to the inspection hole 112a.

A structure of the electrostatic chuck 10 with reference to FIGS. 12 and 13 may be substantially the same as or similar to the structure of the electrostatic chuck 10 described with reference to FIGS. 9 and 11, except for the structure of the insulating layer 140a. Hereinafter, overlapping descriptions with those described with reference to FIGS. 9 and 11 may be omitted or briefly described.

Referring to FIGS. 12 and 13, the electrostatic chuck 10 may have a first inspection hole 112a penetrating a third adhesive layer 156 and a cushion layer 160 in the thickness direction (e.g., the third direction DR3). The electrostatic chuck 10 may have a second inspection hole 102 penetrating a first adhesive layer 152 and an electrode layer 120 in the thickness direction (e.g., the third direction DR3). The electrostatic chuck 10 may have a third inspection hole 104 penetrating a second adhesive layer 154 in the thickness direction (e.g., the third direction DR3).

In an embodiment, the first inspection hole 112a, the second inspection hole 102, and the third inspection hole 104 may overlap each other in a plan view. In an embodiment, the first inspection hole 112a may be connected to (e.g., may be in fluid communication with) a through hole 116a. In an embodiment, the through hole 116a may not be connected to the second inspection hole 102 and the third inspection hole 104.

In an embodiment, the electrostatic chuck may include an insulating layer 140a. The insulating layer 140a may include a first insulating layer 142a and a second insulating layer 146a. In an embodiment, the first insulating layer 142a may overlap the first inspection hole 112a in a plan view. In an embodiment, the second insulating layer 146a may overlap the first inspection hole 112a in a plan view.

In an embodiment, each of the first insulating layer 142a and the second insulating layer 146a may include a transparent material. Accordingly, when light is introduced through the through hole 116a, the light may be transmitted through the transparent dielectric layer 100, the first insulating layer 142a, and the second insulating layer 146a. For example, the light may be introduced through the through hole 116a, pass sequentially through the first inspection hole 112a, the second insulating layer 146a, the third inspection hole 104, the first insulating layer 142a, the second inspection hole 102, and the dielectric layer 100 to reach the target substrate 20.

In an embodiment, the first insulating layer 142a may include the same material as the dielectric layer 100. For example, the first insulating layer 142a may include a transparent polyimide. In an embodiment, the second insulating layer 146a may include the same material as the dielectric layer 100. For example, the second insulating layer 146a may include a transparent polyimide.

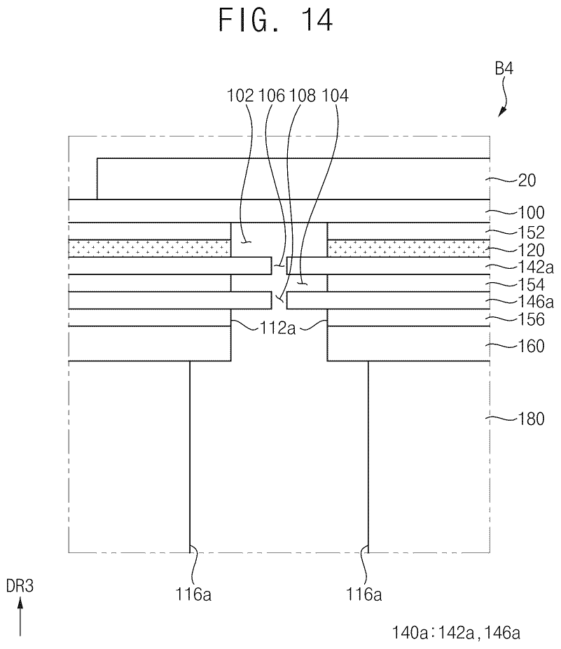

FIG. 14 is a cross-sectional view of the area B4 in FIG. 10 according to another embodiment. For example, FIG. 14 is cross-sectional view of the electrostatic chuck 10 and the target substrate 20 adjacent to the inspection hole 112a according to another embodiment.

A structure of the electrostatic chuck 10 described with reference to FIG. 14 may be substantially the same as or similar to the structure of the electrostatic chuck 10 described with reference to FIGS. 12 and 13, except that a first connecting hole 106 and a second connecting hole 108 are formed. Hereinafter, overlapping descriptions with those described with reference to FIGS. 12 and 13 may be omitted or briefly described.

Referring to FIG. 14, a first connecting hole 106 may be formed in the first insulating layer 142a. For example, the first connecting hole 106 may penetrate the first insulating layer 142a in the thickness direction (e.g., the third direction DR3). In an embodiment, the first connecting hole 106 may connect (e.g., may extend between) the second inspection hole 102 and the third inspection hole 104.

A second connecting hole 108 may be formed in the second insulating layer 146a. For example, the second connecting hole 108 may penetrate the second insulating layer 146a in the thickness direction (e.g., the third direction DR3). In an embodiment, the second connecting hole 108 may connect the first inspection hole 112a and the third inspection hole 104.

In an embodiment, the first inspection hole 112a, the second inspection hole 102, and the third inspection hole 104 may be connected to each other through the first connecting hole 106 and the second connecting hole 108. Accordingly, gases remaining in each of the second inspection hole 102 and the third inspection hole 104 may be discharged through the first connecting hole 106 and the second connecting hole 108, thereby preventing a phenomenon in which gases are trapped inside the electrostatic chuck 10 and damage or defects occur in the internal configuration of the electrostatic chuck 10.

In an embodiment, the first connecting hole 106 and the second connecting hole 108 may overlap each other in a plan view. For example, the first connecting hole 106 and the second connecting hole 108 may be arranged at the same location in a plan view. In an embodiment, an imaginary line connecting the center of the first connecting hole 106 and the center of the second connecting hole 108 may be parallel to the third direction DR3. In an embodiment, in a cross-sectional view, the shapes of the first inspection hole 112a, the second inspection hole 102, the third inspection hole 104, and the through hole 116a may be symmetrical with respect to the imaginary line. However, the arrangement relationship of the first connecting hole 106 and the second connecting hole 108 according to the embodiments of the present disclosure may not be limited thereto.

In an embodiment, in a plan view, a size of the first connecting hole 106 may be less than each of sizes of the second inspection hole 102 and the third inspection hole 104. In an embodiment, in a plan view, the size of the second connecting hole 108 may be less than each of the sizes of the first inspection hole 112a and the third inspection hole 104. However, the sizes of the first connecting hole 106 and the second connecting hole 108 according to the embodiments of the present disclosure may not be limited thereto. In addition, the number, locations, and the like of the first connecting hole 106 and the second connecting hole 108 according to the embodiments of the present disclosure may not be limited thereto.

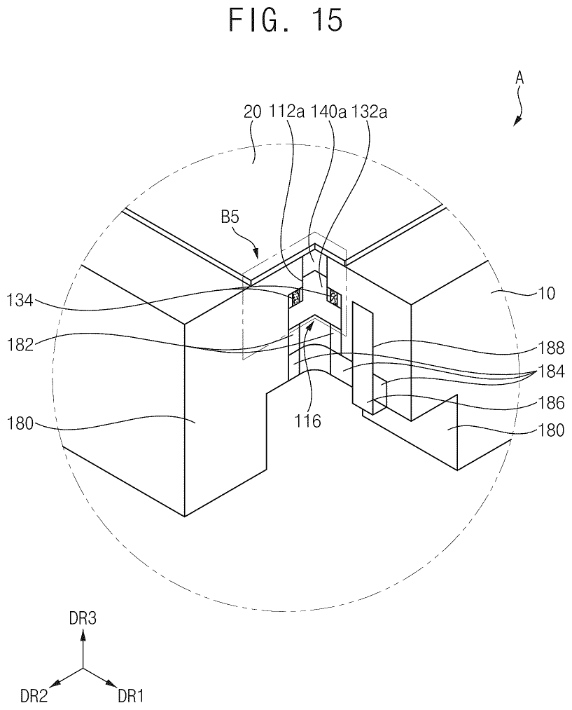

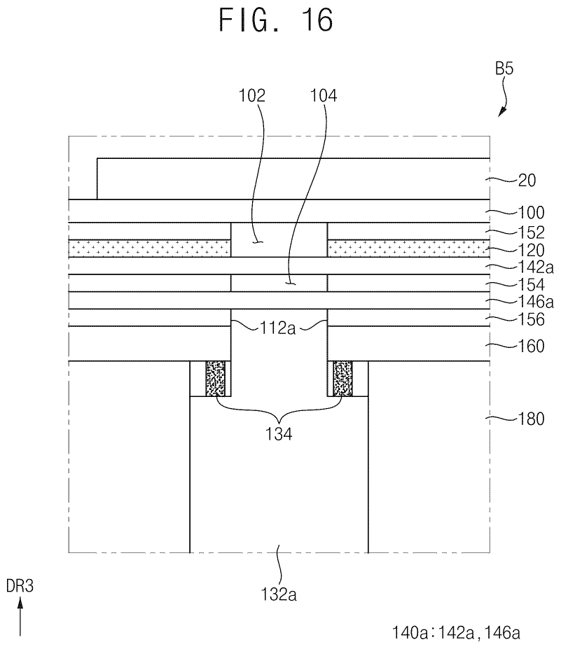

FIG. 15 is a perspective cross-sectional view of the area A of the electrostatic chuck illustrated in FIG. 1 according to another embodiment. FIG. 16 is a cross-sectional view of the area B5 in FIG. 15. For example, FIG. 16 is a cross-sectional view of the electrostatic chuck 10 and the target substrate 20 adjacent to the inspection hole 112a.

A structure of the electrostatic chuck 10 described with reference to FIGS. 15 and 16 may be substantially the same as or similar to the structure of the electrostatic chuck 10 described with reference to FIGS. 2 and 5, except for the structures of the transparent portion 132a and the insulating layer 140a.

In addition, the structure of the electrostatic chuck 10 described with reference to FIGS. 15 and 16 may be substantially the same as or similar to the structure of the electrostatic chuck 10 described with reference to FIG. 13, except that the transparent portion 132a and a buffer pad 134 are arranged.

Hereinafter, overlapping descriptions with those described with reference to FIGS. 2, 5, and 13 may be omitted or briefly described.

Referring to FIGS. 15 and 16, the transparent portion 132a may fill the first inspection hole 112a penetrating the third adhesive layer 156 and the cushion layer 160 in the thickness direction (e.g., the third direction DR3). For example, the transparent portion 132a may fill the first inspection hole 112a and may contact the second insulating layer 146a. In addition, in a cross-sectional view, a buffer pad 134 may be arranged between the second portion, which is a lower portion of the transparent portion 132a, and the cushion layer 160. In an embodiment, the first insulating layer 142a and the second insulating layer 146a may include a transparent material.

In an embodiment, the transparent portion 132a may overlap the second inspection hole 102 and the third inspection hole 104 in a plan view. In an embodiment, in a plan view, the size of the first portion, which is an upper portion of the transparent portion 132a, may be the same as each of the sizes of the second inspection hole 102 and the third inspection hole 104. However, the sizes of the first portion of the transparent portion 132a, the second inspection hole 102, and the third inspection hole 104 according to the embodiments of the present disclosure may not be limited thereto.

Below the transparent portion 132a, a first level adjuster 182 and a second level adjuster 184 may be arranged for adjusting the level of the transparent portion 132a or for supporting the transparent portion 132a. In addition, a third level adjuster 186 for adjusting the levels of the first level adjuster 182 and the second level adjuster 184 or fixing the first level adjuster 182 and the second level adjuster 184 may fill a fixing hole 188 and may be coupled to a body portion 180.

In an embodiment, the transparent portion 132a may include a transparent material. For example, the transparent portion 132a may include quartz, glass, or silicone. These may be used alone or in combination with each other. In an embodiment, the transparent portion 132a may have a light transmittance of about 90% or more. Preferably, the transparent portion 132a may have a light transmittance in a range of about 95% to about 99.999%.

A length of the first portion, which is an upper portion of the transparent portion 132a shown in FIG. 16, in the third direction DR3 may be less than a length of the first portion of the transparent portion 132a shown in FIG. 5 in the third direction DR3. Because the length of the first inspection hole 112a shown in FIG. 16 in the third direction DR3 is less than the length of the inspection hole 112 shown in FIG. 5 in the third direction DR3, the length of the first portion of the transparent portion 132a in the third direction DR3 may be relatively less.

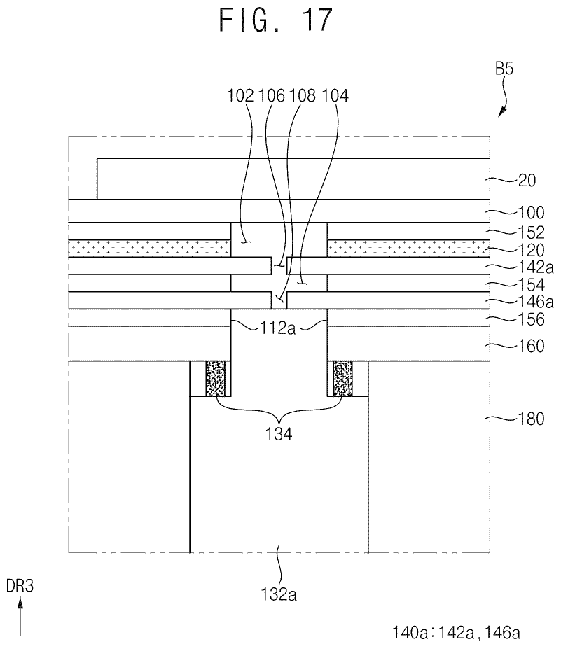

FIG. 17 is a cross-sectional view of the area B5 in FIG. 15 according to another embodiment. For example, FIG. 17 is a cross-sectional view of the electrostatic chuck 10 and the target substrate 20 adjacent to the inspection hole 112a according to another embodiment.

A structure of the electrostatic chuck 10 with reference to FIG. 17, except that a first connecting hole 106 and a second connecting hole 108 are formed, may be substantially the same as or similar to the structure of the electrostatic chuck 10 described with reference to FIGS. 15 and 16. Hereinafter, descriptions overlapping with the contents described with reference to FIGS. 15 and 16 may be omitted or briefly described.

Referring to FIG. 17, a first connecting hole 106 penetrating the first insulating layer 142a in the thickness direction (e.g., the third direction DR3) may be formed in the first insulating layer 142a, and a second connecting hole 108 exposing an upper surface of the transparent portion 132a may be formed in the second insulating layer 146a. In an embodiment, the second inspection hole 102 may be connected to the third inspection hole 104 through the first connecting hole 106, and the third inspection hole 104 may extend to the upper surface of the transparent portion 132a through the second connecting hole 108.

In an embodiment, each of the second inspection hole 102, the third inspection hole 104, the first connecting hole 106, and the second connecting hole 108 may overlap the transparent portion 132a in a plan view. In an embodiment, the second connecting hole 108 may expose a portion of the upper surface of the transparent portion 132a. For example, in a plan view, a size of the second connecting hole 108 may be less than a size of the transparent portion 132a.

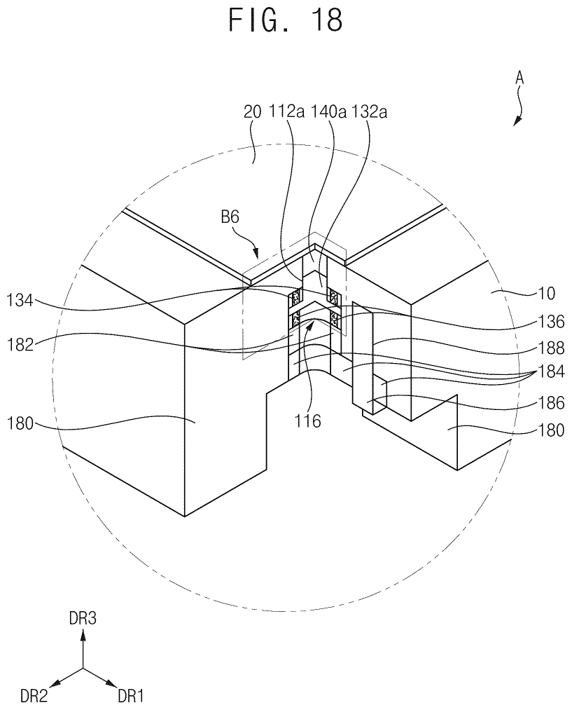

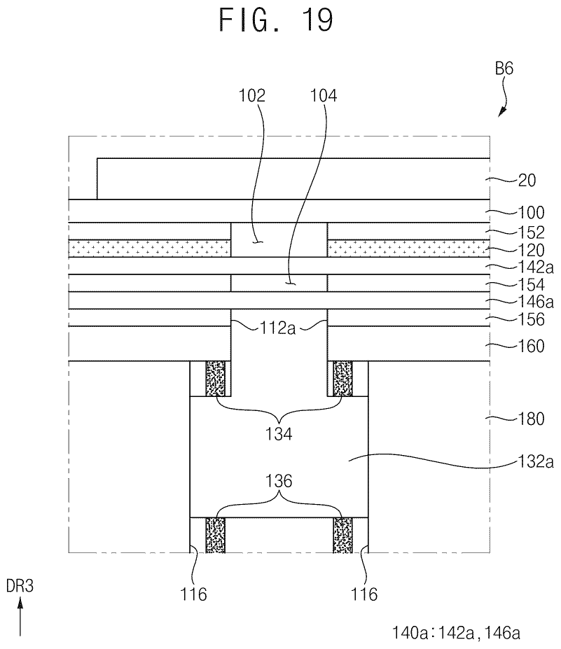

FIG. 18 is a perspective cross-sectional view of the area A of the electrostatic chuck illustrated in FIG. 1 according to another embodiment. FIG. 19 is a cross-sectional view of the area B6 in FIG. 18. For example, FIG. 19 is a cross-sectional view of the electrostatic chuck 10 and the target substrate 20 adjacent to the inspection hole 112a.

Referring to FIGS. 18 and 19, the structure of the electrostatic chuck 10, except for the structures of the transparent portion 132a and the insulating layer 140a, may be substantially the same as or similar to the structure of the electrostatic chuck 10 described with reference to FIGS. 7 and 8.

In addition, the structure of the electrostatic chuck 10 described with reference to FIGS. 18 and 19, except that a second buffer pad 136 is further arranged, may be substantially the same as or similar to the structure of the electrostatic chuck 10 described with reference to FIGS. 15 and 16. Hereinafter, descriptions overlapping with the contents described with reference to FIGS. 7, 8, 15, and 16 may be omitted or briefly described.

Referring to FIGS. 18 and 19, in an embodiment, the electrostatic chuck 10 may include a first buffer pad 134 and a second buffer pad 136 surrounding (e.g., extending around a periphery of) at least a portion of the transparent portion 132a. In an embodiment, the first buffer pad 134 may be arranged in a space between the first portion, which is an upper portion of the transparent portion 132a, and the body portion 180, and the second buffer pad 136 may be arranged under the transparent portion 132a.

In an embodiment, the first buffer pad 134 may be spaced apart from each of the second inspection hole 102 and the third inspection hole 104 in a plan view. For example, in a plan view, the first buffer pad 134 may be spaced apart from each of the second inspection hole 102 and the third inspection hole 104 and may surround the second inspection hole 102 and the third inspection hole 104.

In an embodiment, the second buffer pad 136 may be spaced apart from each of the second inspection hole 102 and the third inspection hole 104 in a plan view. For example, in a plan view, the second buffer pad 136 may be spaced apart from each of the second inspection hole 102 and the third inspection hole 104 and may surround (e.g., may extend around) the second inspection hole 102 and the third inspection hole 104.

A length of the second portion, which is a lower portion of the transparent portion 132a shown in FIG. 19, in the third direction DR3 may be less than a length of the second portion of the transparent portion 132a shown in FIG. 17 in the third direction DR3. For example, because the second buffer pad 136 is arranged under the second portion of the transparent portion 132a, the length of the second portion of the transparent portion 132a in the third direction DR3 may be relatively reduced.

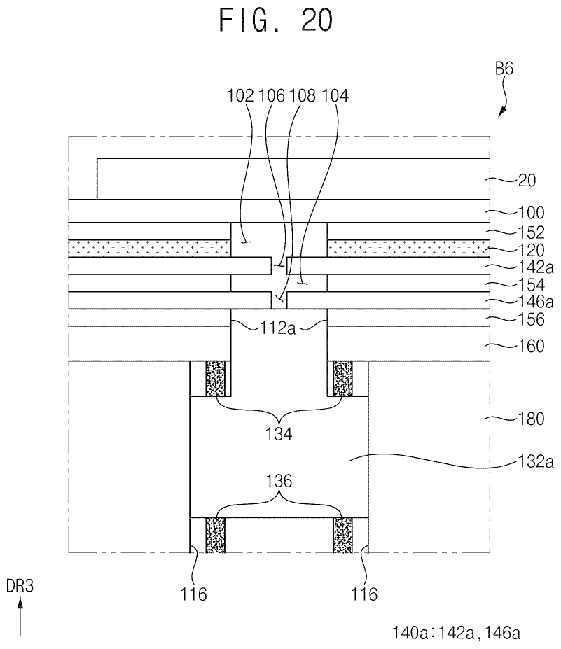

FIG. 20 is a cross-sectional view of the area B6 in FIG. 18. FIG. 20 is a cross-sectional view of the electrostatic chuck 10 and the target substrate 20 adjacent to the inspection hole 112a.

Referring to FIG. 20, the structure of the electrostatic chuck 10, except for the formation of the first connecting hole 106 and the second connecting hole 108, may be substantially the same as or similar to the structure of the electrostatic chuck 10 described with reference to FIGS. 18 and 19. Hereinafter, descriptions overlapping with the contents described with reference to FIGS. 18 and 19 may be omitted or briefly described.

Referring to FIG. 20, in an embodiment, the second buffer pad 136 may be spaced apart from the first connecting hole 106 in a plan view. For example, in a plan view, the first connecting hole 106 may be located in the second buffer pad 136. In addition, the second buffer pad 136 may be spaced apart from the first connecting hole 106 and may surround (e.g., may extend around a periphery of) the first connecting hole 106.

In an embodiment, the second buffer pad 136 may be spaced apart from the second connecting hole 108 in a plan view. For example, in a plan view, the second connecting hole 108 may be located in the second buffer pad 136. In addition, the second buffer pad 136 may be spaced apart from the second connecting hole 108 and may surround (e.g., may extend around) the second connecting hole 108.

As described above, according to embodiments of the present disclosure, the dielectric layer 100 in the electrostatic chuck 10 on which the target substrate 20 is placed may be transparent. Accordingly, when light is irradiated toward the through hole 116 and the inspection hole 112 from under the electrostatic chuck 10, the alignment mark 220 arranged in the target substrate 20 disposed on the dielectric layer 100 may be easily recognized. Therefore, the accuracy and efficiency of inspection and alignment using the electrostatic chuck 10 may be improved.

FIG. 21 is a diagram of a substrate treating apparatus including the electrostatic chuck shown in FIG. 1 according to an embodiment.

Referring to FIG. 21, a substrate treating apparatus 1000, according to an embodiment of the present disclosure, may include a process chamber 1020, a lower electrostatic chuck 1220, an upper electrostatic chuck 1240, a lower target substrate 1420, an upper target substrate 1440, a lower imaging part 1620, a lower illumination part 1640, an upper imaging part 1820, and an upper illumination part 1840.

In the specification, the lower electrostatic chuck 1220 and the upper electrostatic chuck 1240 may be referred to as the first electrostatic chuck and the second electrostatic chuck, respectively. In addition, the lower target substrate 1420 and the upper target substrate 1440 may be referred to as the first target substrate and the second target substrate, respectively. In addition, the lower imaging part 1620 and the upper imaging part 1820 may be referred to as the first imaging part and the second illumination part, respectively. In addition, light emitted from the lower illumination part 1640 may be referred to as the first light, and light emitted from the upper illumination part 1840 may be referred to as the second light.

The process chamber 1020 may provide a space for substrate processing. For example, the process chamber 1020 may provide a space for performing alignment and/or bonding of substrates. In an embodiment, the process chamber 1020 may form or maintain a vacuum state depending on the process being performed.

Referring further to FIG. 21, each of the lower electrostatic chuck 1220 and the upper electrostatic chuck 1240 may be arranged in the process chamber 1020. Each of the lower electrostatic chuck 1220 and the upper electrostatic chuck 1240 may correspond to the electrostatic chuck 10. For example, each of the lower electrostatic chuck 1220 and the upper electrostatic chuck 1240 may be a dielectric layer 100 having a transparent surface on which a substrate is placed.

The lower target substrate 1420 and the upper target substrate 1440 may correspond to the target substrate 20. The lower target substrate 1420 may be placed on the lower electrostatic chuck 1220. For example, the lower target substrate 1420 may be placed on the dielectric layer 100 of the lower electrostatic chuck 1220. The upper target substrate 1440 may be placed on the upper electrostatic chuck 1240. For example, the upper target substrate 1440 may be placed on the dielectric layer 100 of the upper electrostatic chuck 1240.

The lower imaging part 1620 may recognize (or may determine) the location of the lower target substrate 1420. The lower illumination part 1640 may irradiate light toward the lower target substrate 1420. For example, through the light emitted from the lower illumination part 1640, the lower imaging part 1620 may recognize (or determine) the location of the lower target substrate 1420 and inspect (e.g., determine) whether or not the lower target substrate 1420 is aligned to a target location. For example, when the light from the lower illumination part 1640 is incident toward the lower electrostatic chuck 1220, the light may be transmitted through the dielectric layer 100, and the lower imaging part 1620 may recognize the location of the lower target substrate 1420.

The upper imaging part 1820 may recognize the location of the upper target substrate 1440. The upper illumination part 1840 may irradiate light toward the upper target substrate 1440. For example, through the light emitted from the upper illumination part 1840, the upper imaging part 1820 may recognize the location of the upper target substrate 1440 and inspect whether or not the upper target substrate 1440 is aligned to a target location. For example, when the light from the upper illumination part 1840 is incident toward the upper electrostatic chuck 1240, the light may be transmitted through the dielectric layer 100 so that the upper imaging part 1820 may recognize the location of the upper target substrate 1440.

In an embodiment, each of the lower imaging part 1620 and the upper imaging part 1820 may be located outside the process chamber 1020. In an embodiment, each of the lower illumination part 1640 and the upper illumination part 1840 may be located outside the process chamber 1020. In an embodiment, each of the lower imaging part 1620 and the upper imaging part 1820 may be an imaging device, such as a camera, that receives light and acquires an image. In an embodiment, each of the lower illumination part 1640 and the upper illumination part 1840 may be a coaxial box light for providing a clear image of the lower target substrate 1420 and the upper target substrate 1440. However, the types of the lower imaging part 1620, the upper imaging part 1820, the lower illumination part 1640, and the upper illumination part 1840 according to embodiments of the present disclosure are not limited thereto.

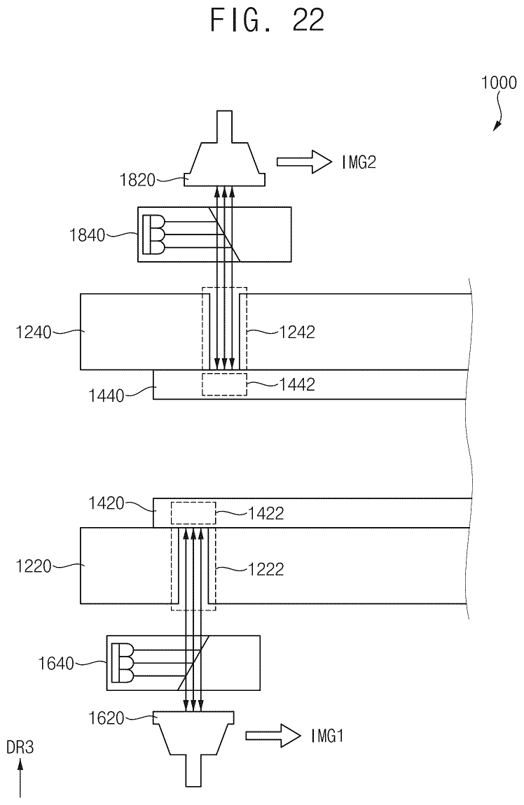

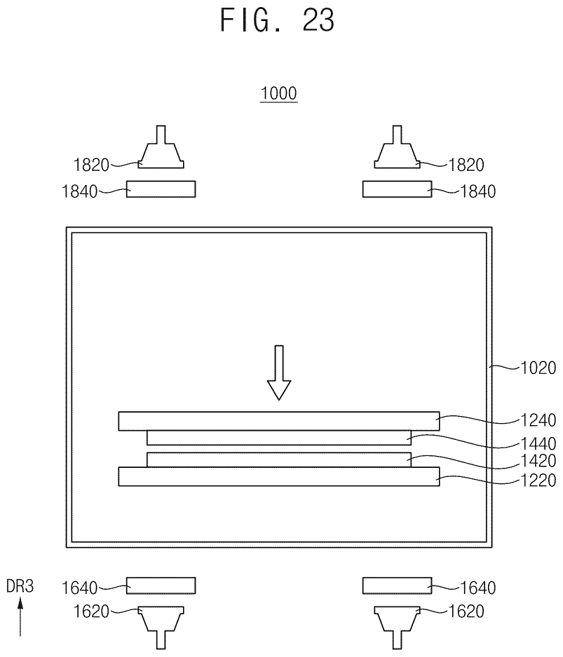

FIGS. 22 and 23 are schematic diagrams illustrating a method for manufacturing a display device using the substrate treating apparatus shown in FIG. 21.

Hereinafter, overlapping descriptions with those described with reference to FIG. 21 may be omitted or briefly described.

Referring to FIGS. 22 and 23, in the process chamber 1020, the lower target substrate 1420 may be placed on the lower electrostatic chuck 1220, and the upper target substrate 1440 may be placed on the upper electrostatic chuck 1240. After the lower target substrate 1420 and the upper target substrate 1440 are placed as described, the inside of the process chamber 1020 may be brought into a vacuum state.

From the outside of the process chamber 1020 in which the vacuum state has been formed, light may be irradiated to the lower electrostatic chuck 1220 and the lower target substrate 1420 through the lower illumination part 1640. For example, the light emitted from the lower illumination part 1640 may pass through the first light transmitting portion 1222 of the lower electrostatic chuck 1220 to reach the first region of interest 1422 of the lower target substrate 1420. Accordingly, the light reflected from the first region of interest 1422 may be received by the lower imaging part 1620, and first image data IMG1 including location information of the first region of interest 1422 may be obtained.

From the outside of the process chamber 1020 in the vacuum state, light may be irradiated from the upper illumination part 1840 to the upper electrostatic chuck 1240 and the upper target substrate 1440. For example, the light emitted from the upper illumination part 1840 may pass through the second light transmitting portion 1242 of the upper electrostatic chuck 1240 to reach the second region of interest 1442 of the upper target substrate 1440. Accordingly, the light reflected from the second region of interest 1442 may be received by the upper imaging part 1820 to obtain second image data IMG2 for the second region of interest 1442.

The first light transmitting portion 1222 and the second light transmitting portion 1242 may correspond to the inspection hole 112, 112a and the through hole 116, 116a shown in FIGS. 2, 7, 9, 12, 15, and 18. In addition, the first region of interest 1422 may be an area in the lower target substrate 1420 in which an alignment mark is arranged. For example, the first region of interest 1422 may be located at a corner of the lower target substrate 1420 in which the alignment mark is arranged. In addition, the second region of interest 1442 may be an area in the upper target substrate 1440 in which an alignment mark is arranged. For example, the second region of interest 1442 may be located at a corner of the upper target substrate 1440 in which the alignment mark is arranged.

After the first image data IMG1 for the lower target substrate 1420 is obtained by the lower imaging part 1620, the lower imaging part 1620, or an external device electrically connected to the lower imaging part 1620, or a user may inspect (e.g., determine) whether or not the lower target substrate 1420 is aligned (e.g., is accurately aligned) on the lower electrostatic chuck 1220 by using the first image data IMG1. When the lower target substrate 1420 is not accurately aligned at a target location on the lower electrostatic chuck 1220, the location of the lower target substrate 1420 may be moved by using a moving part in the process chamber 1020.

After the second image data IMG2 for the upper target substrate 1440 is obtained by the upper imaging part 1820, the upper imaging part 1820, or an external device electrically connected to the upper imaging part 1820, or a user may inspect whether or not the upper target substrate 1440 is accurately aligned on the upper electrostatic chuck 1240 by using the second image data IMG2. When the upper target substrate 1440 is not accurately aligned at a target location on the upper electrostatic chuck 1240, the location of the upper target substrate 1440 may be moved by using a moving part in the process chamber 1020.

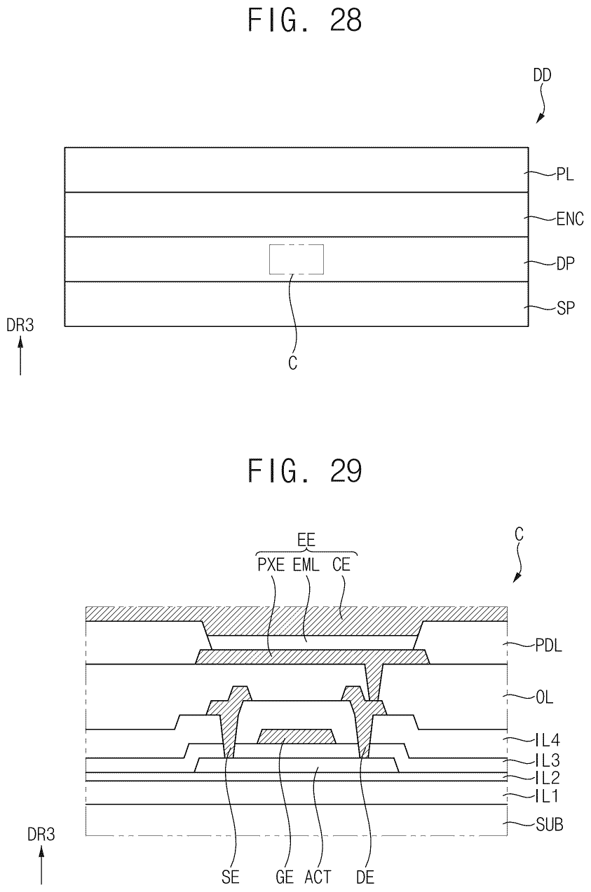

When the lower target substrate 1420 and the upper target substrate 1440 are accurately aligned at target locations on the lower electrostatic chuck 1220 and the upper electrostatic chuck 1240, respectively, a process of bonding the lower target substrate 1420 and the upper target substrate 1440 may be performed. For example, the upper target substrate 1440 may be moved in a direction opposite to the third direction DR3 so that the lower target substrate 1420 and the upper target substrate 1440 may be bonded to each other. Accordingly, the display device DD shown in FIG. 28 and the electronic devices shown in FIG. 30 including the bonded lower target substrate 1420 and upper target substrate 1440 may be manufactured.

In a conventional substrate treating apparatus including a lower electrostatic chuck and an upper electrostatic chuck that do not include the transparent dielectric layer 100 shown in FIG. 1, illumination parts for obtaining location information of the lower target substrate and the upper target substrate were disposed in the process chamber. Accordingly, after illuminating the location information of the lower target substrate and the upper target substrate by the illumination parts, location alignment of the lower target substrate and the upper target substrate was performed, and the door of the process chamber was closed to form a vacuum state inside the process chamber.

As a result, because the illumination parts were located in the process chamber in the conventional substrate treating apparatus, the size of the process chamber was relatively large, and thus, the time required to form the vacuum state was relatively long. In addition, when the lower target substrate and the upper target substrate were bonded to each other after forming the vacuum state, an alignment error between the lower target substrate and the upper target substrate occurred due to a minute locational change caused by the vacuum formation.

As described above, in the substrate treating apparatus 1000 shown in FIG. 21, because the dielectric layer on which the substrate is placed (e.g., the dielectric layer 100 shown in FIG. 1) is transparent, the locations of the target substrates (e.g., the lower target substrate 1420 and the upper target substrate 1440) may be measured for each of the target substrates by the illumination parts (e.g., the lower imaging part 1620 and the upper imaging part 1820) disposed outside the process chamber 1020. Accordingly, time required to form the vacuum state may be relatively reduced, and because the locations of the target substrates may be determined after forming the vacuum state to align the target substrates, the alignment error between the target substrates may be prevented or reduced.

Therefore, a substrate treating apparatus 1000 having a structure that shortens process time and cost may be provided. In addition, because the display device or the electronic device manufactured using the substrate treating apparatus 1000 has a relatively reduced occurrence rate of alignment errors, the display quality may be improved, defective occurrence may be reduced, and durability may be improved.

FIG. 24 is a diagram of a substrate treating apparatus including the electrostatic chuck shown in FIG. 1 according to another embodiment.

A structure of the substrate treating apparatus 2000 described with reference to FIG. 24 may be substantially the same as or similar to the structure of the substrate treating apparatus 1000 described with reference to FIG. 21, except that the imaging part and the illumination part are not arranged above the process chamber, and the structure of the upper electrostatic chuck is different.

Hereinafter, the contents overlapping with those described with reference to FIG. 21 may be omitted or briefly described.

Referring to FIG. 24, a substrate treating apparatus 2000, according to an embodiment of the present disclosure, may include a process chamber 2020, a lower electrostatic chuck 2220, an upper electrostatic chuck 2240, a lower target substrate 2420, an upper target substrate 2440, an imaging part 2620, and a illumination part 2640. The process chamber 2020 may correspond to the process chamber 1020 shown in FIG. 21.

In the present specification, the lower electrostatic chuck 2220 and the upper electrostatic chuck 2240 may be referred to as a first electrostatic chuck and a second electrostatic chuck, respectively. In addition, the lower target substrate 2420 and the upper target substrate 2440 may be referred to as a first target substrate and a second target substrate, respectively. In addition, the imaging part 2620 may be referred to as a first illumination part. In addition, the light emitted from the illumination part 2640 may be referred to as first light.

Referring further to FIG. 1, the lower electrostatic chuck 2220 and the upper electrostatic chuck 2240 may be arranged in the process chamber 2020. The lower electrostatic chuck 2220 may correspond to the electrostatic chuck 10 including a dielectric layer 100 having one surface on which a substrate is seated and which is transparent. The upper electrostatic chuck 2240 may be an electrostatic chuck including a dielectric layer having one surface on which a substrate is seated and which is not transparent. In other words, the upper electrostatic chuck 2240 may not be (or may be different from) the electrostatic chuck 10 shown in FIG. 1. Accordingly, when light is irradiated toward the upper electrostatic chuck 2240, the light may not be transmitted through the upper electrostatic chuck 2240, and thus, the light irradiated toward the upper electrostatic chuck 2240 may not reach the upper target substrate 2440. The lower electrostatic chuck 2220 may correspond to the lower electrostatic chuck 1220 shown in FIG. 21.

The imaging part 2620 may recognize the locations of each of the lower target substrate 2420 and the upper target substrate 2440. The illumination part 2640 may irradiate light toward the lower target substrate 2420 and the upper target substrate 2440. For example, due to the light emitted from the illumination part 2640, the imaging part 2620 may recognize the locations of each of the lower target substrate 2420 and the upper target substrate 2440. In addition, through the recognized locations of each of the lower target substrate 2420 and the upper target substrate 2440, whether or not each of the lower target substrate 2420 and the upper target substrate 2440 is aligned at a target location may be easily inspected.

For example, when the light from the illumination part 2640 is incident toward the lower electrostatic chuck 2220, the light may pass through the dielectric layer 100 of the lower electrostatic chuck 2220, and the imaging part 2620 may recognize the locations of the lower target substrate 2420 and the upper target substrate 2440 concurrently (or simultaneously) or may recognize the locations of each of the lower target substrate 2420 and the upper target substrate 2440.

The lower target substrate 2420 and the upper target substrate 2440 may correspond to the lower target substrate 1420 and the upper target substrate 1440 shown in FIG. 24. In addition, the imaging part 2620 and the illumination part 2640 may correspond to the lower imaging part 1620 and the lower illumination part 1640 shown in FIG. 24.

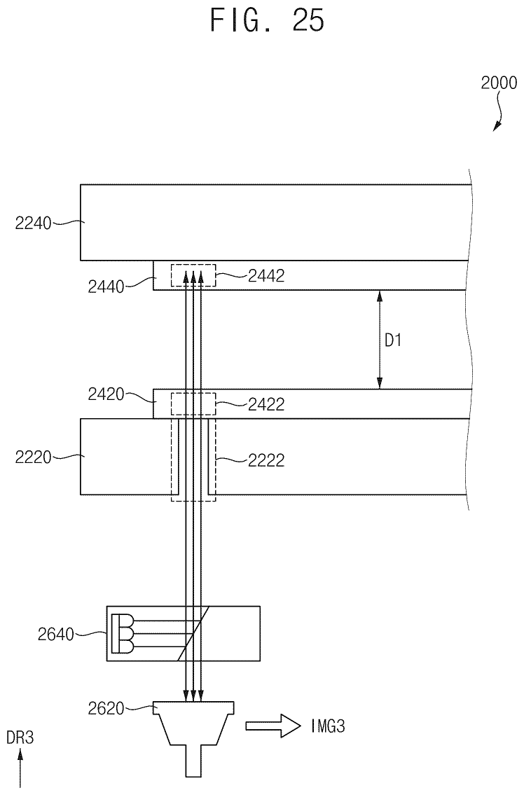

FIGS. 25, 26, and 27 are diagrams illustrating a method for manufacturing a display device by using the substrate treating apparatus shown in FIG. 24.

Hereinafter, content overlapping with the description made with reference to FIG. 24 may be omitted or briefly described.

Referring to FIG. 25, in the process chamber 2020, the lower target substrate 2420 may be seated on the lower electrostatic chuck 2220, and the upper target substrate 2440 may be seated on the upper electrostatic chuck 2240. After the lower target substrate 2420 and the upper target substrate 2440 are seated, the inside of the process chamber 2020 may be brought into a vacuum state.

From outside the process chamber 2020 in which the vacuum state has been formed, light may be irradiated to the lower electrostatic chuck 2220, the lower target substrate 2420, and the upper target substrate 2440 through the illumination part 2640. For example, the light emitted from the illumination part 2640 may pass through the first light transmission portion 2222 of the lower electrostatic chuck 2220 and reach the first region of interest 2422 of the lower target substrate 2420. In addition, the light may pass through the lower electrostatic chuck 2220 and the lower target substrate 2420 to reach the second region of interest 2442 of the upper target substrate 2440. For example, when the light is irradiated from the illumination part 2640, the light may reach the first region of interest 2422 and the second region of interest 2442 when the distance between the lower target substrate 2420 and the upper target substrate 2440 is maintained at the first distance D1. Accordingly, the light reflected from each of the first region of interest 2422 and the second region of interest 2442 may be received by the imaging part 2620, and third image data IMG3 regarding the positions of the first region of interest 2422 and the second region of interest 2442 may be obtained.

The first light transmission portion 2222 may correspond to the inspection hole 112, 112a and the through hole 116, 116a shown in FIGS. 2, 7, 9, 12, 15, and 18. In addition, the first region of interest 2422 may be an area in which an alignment mark is arranged in the lower target substrate 2420. For example, the first region of interest 2422 may be an area located at a corner of the lower target substrate 2420 in which the alignment mark is arranged. The second region of interest 2442 may be an area in which an alignment mark is arranged in the upper target substrate 2440. For example, the second region of interest 2442 may be an area located at a corner of the upper target substrate 2440 in which the alignment mark is arranged.

After the third image data IMG3 is obtained by the imaging part 2620, the imaging part 2620 or an external device electrically connected to the imaging part 2620 or a user may inspect whether or not each of the lower target substrate 2420 and the upper target substrate 2440 is accurately aligned. If each of the lower target substrate 2420 and the upper target substrate 2440 is not accurately aligned at a target position, the position of the upper target substrate 2440 may be moved by using the moving part in the process chamber 2020.

When each of the lower target substrate 2420 and the upper target substrate 2440 is accurately aligned at a target position, as illustrated in FIG. 23, a process of bonding the lower target substrate 2420 and the upper target substrate 2440 may be performed. Accordingly, the lower target substrate 2420 and the upper target substrate 2440 may be bonded to each other. Therefore, the display device DD shown in FIG. 28 and the electronic devices shown in FIG. 30 including the bonded lower target substrate 2420 and upper target substrate 2440 may be manufactured.

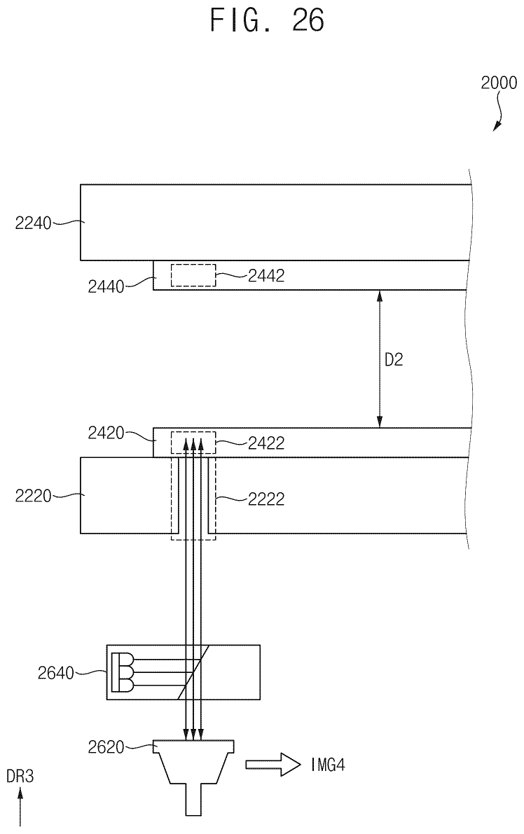

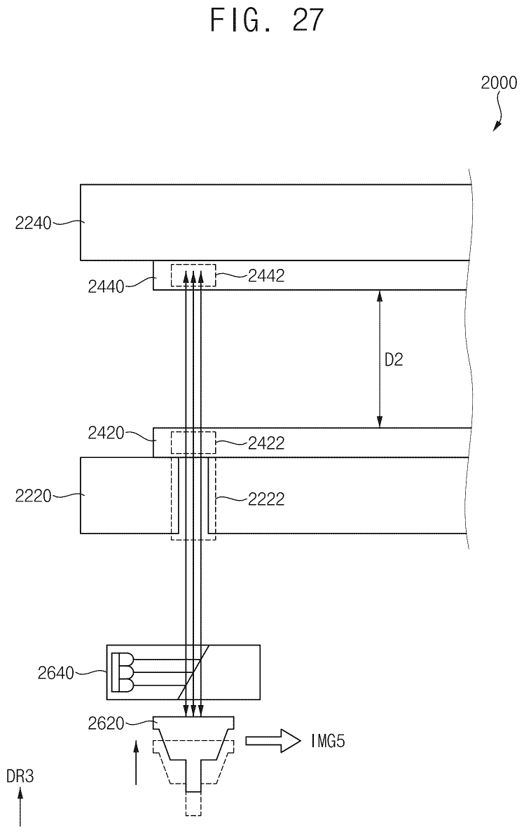

Referring to FIGS. 26 and 27, when the distance between the lower target substrate 2420 and the upper target substrate 2440 is maintained at a second distance D2 greater than the first distance D1 shown in FIG. 25, the light emitted from the illumination part 2640 may not reach the second region of interest 2442, and the imaging part 2620 may not obtain a clear image of the second region of interest 2442. For example, when the distance between the lower target substrate 2420 and the upper target substrate 2440 is maintained at the second distance D2 greater than the first distance D1, the focal distance of the imaging part 2620 may be located between the lower target substrate 2420 and the upper target substrate 2440, not on the second region of interest 2442 of the upper target substrate 2440. Accordingly, the illumination part 2640 may obtain fourth image data IMG4 including position information of the first region of interest 2422.

After the illumination part 2640 obtains the fourth image data IMG4, the illumination part 2640 may move along a direction parallel to the third direction DR3 to obtain a clear image of the second region of interest 2442. For example, the illumination part 2640 may move along the third direction DR3 so that the focal distance is located on the second region of interest 2442 of the upper target substrate 2440. In FIG. 27, the illumination part 2640 is illustrated as being moved closer to the lower electrostatic chuck 2220; however, the movement of the illumination part 2640 according to embodiments of the present disclosure is not limited thereto, and when the focal distance of the illumination part 2640 is set farther than the second region of interest 2442, the illumination part 2640 may be moved away from the lower electrostatic chuck 2220.

As the illumination part 2640 moves, the illumination part 2640 may obtain fifth image data IMG5 including position information of the second region of interest 2442. Accordingly, the imaging part 2620 or an external device electrically connected to the imaging part 2620 or a user may inspect whether or not each of the lower target substrate 2420 and the upper target substrate 2440 is accurately aligned by using the fourth image data IMG4 and the fifth image data IMG5. If each of the lower target substrate 2420 and the upper target substrate 2440 is not accurately aligned at a target position, the position of the upper target substrate 2440 may be moved by using the moving part in the process chamber 2020.

As described above, in the substrate treating apparatus 2000 shown in FIG. 24, because the dielectric layer (e.g., the dielectric layer 100 shown in FIG. 1) on which the substrate is seated is transparent, the positions of the target substrates (e.g., the lower target substrate 1420 and the upper target substrate 1440) may be concurrently (or simultaneously) measured by the illumination part (e.g., the imaging part 2620) disposed outside the process chamber 1020. Accordingly, the time taken to form the vacuum state is relatively reduced, and after the vacuum state is formed, the positions of the target substrates may be determined to align the target substrates, thereby preventing or reducing alignment errors between the target substrates.

Therefore, the substrate treating apparatus 2000 having a structure that shortens process time and cost may be provided. In addition, because the occurrence rate of alignment errors is relatively reduced in the display device or the electronic device manufactured using the substrate treating apparatus 2000, the display quality is improved, defect occurrence is reduced, and durability may be enhanced.

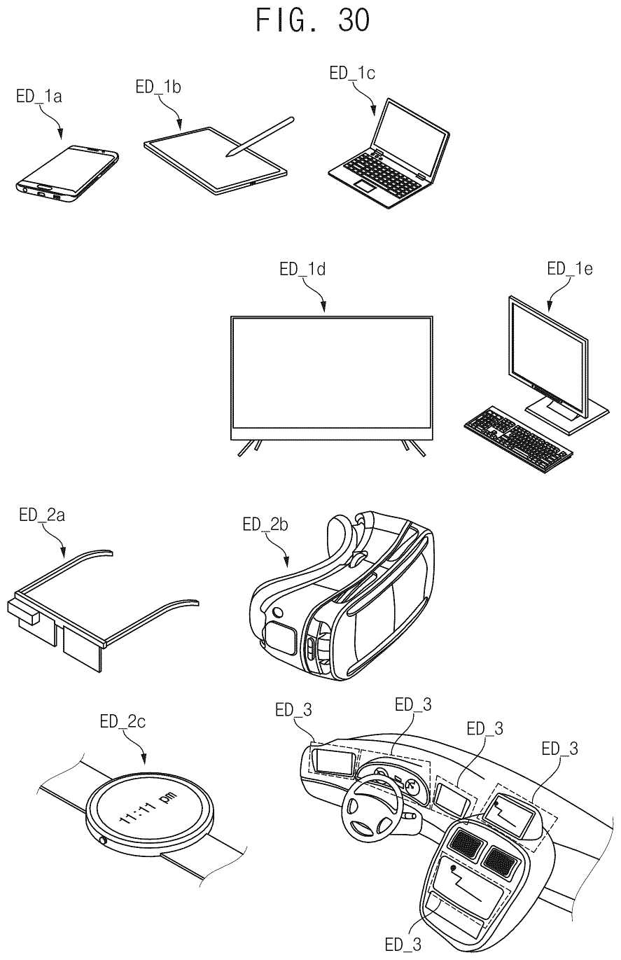

FIG. 28 is a diagram for explaining the target substrate shown in FIG. 1. FIG. 29 is a cross-sectional view of the area C in FIG. 28.

Referring to FIGS. 28 and 29, a display device DD may be manufactured by using an electrostatic chuck (e.g., the electrostatic chuck 10 shown in FIG. 1) and a substrate treating apparatus including the electrostatic chuck (e.g., the substrate treating apparatus 1000 shown in FIG. 21 or the substrate treating apparatus shown in FIG. 24). The display device DD may include a display panel DP, an encapsulation substrate ENC, a protection layer PL, and a lower support layer SP.

In an embodiment, at least one of the display panel DP, the encapsulation substrate ENC, the protection layer PL, and the lower support layer SP may be a target substrate (e.g., the target substrate 20 shown in FIG. 1). For example, the target substrate may be the display panel DP or the encapsulation substrate ENC as the encapsulation substrate.

In an embodiment, at least two of the display panel DP, the encapsulation substrate ENC, the protection layer PL, and the lower support layer SP may be a lower target substrate (e.g., the lower target substrate 1420 shown in FIG. 21 or the lower target substrate 2420 shown in FIG. 24) and an upper target substrate 1440. For example, the lower target substrate may be the display panel DP, and the upper target substrate may be the encapsulation substrate ENC as the encapsulation substrate.

However, the types of the target substrate, the lower target substrate, and the upper target substrate according to the embodiments of the present disclosure may not be limited thereto, and each of the target substrate, the lower target substrate, and the upper target substrate may be various substrate-type components included in the display device DD.

The display panel DP may include a base substrate SUB, a first insulating layer IL1, a second insulating layer IL2, an active layer ACT, a third insulating layer IL3, a gate electrode GE, a fourth insulating layer IL4, a source electrode SE, a drain electrode DE, an organic layer OL, a light-emitting element EE, and a pixel defining layer PDL. The light-emitting element EE may include a pixel electrode PXE, a light-emitting layer EML, and a common electrode CE.

The display panel DP may include a structure (e.g., a pixel) for emitting light. The pixel may include a pixel circuit portion and the light-emitting element EE. The pixel circuit portion may include at least one transistor. The transistor may include the active layer ACT, the gate electrode GE, the source electrode SE, and the drain electrode DE.

The base substrate SUB may form the base of the display panel DP. In an embodiment, the base substrate SUB may be a glass substrate. In an embodiment, the base substrate SUB may be a silicon wafer. In an embodiment, the base substrate SUB may include at least one barrier layer including an organic material. However, the type of the base substrate SUB according to the embodiments of the present disclosure may not be limited thereto.

The first insulating layer IL1 may be arranged on the base substrate SUB. In an embodiment, the first insulating layer IL1 may include an inorganic insulating material. The first insulating layer IL1 may prevent impurities from diffusing from the base substrate SUB to the active layer ACT. The second insulating layer IL2 may be arranged on the first insulating layer IL1. In an embodiment, the second insulating layer IL2 may include an inorganic insulating material.

The active layer ACT may be arranged on the second insulating layer IL2. In an embodiment, the active layer ACT may include an oxide semiconductor or polycrystalline silicon. However, the type of material included in the active layer ACT according to the embodiments of the present disclosure may not be limited thereto.

The third insulating layer IL3 may be arranged on the active layer ACT. In an embodiment, the third insulating layer IL3 may cover the active layer ACT. In an embodiment, the third insulating layer IL3 may include an inorganic insulating material.

The gate electrode GE may be arranged on the third insulating layer IL3. In an embodiment, the gate electrode GE may include a conductive material. The gate electrode GE may overlap the active layer ACT in a plan view. For example, the portion where the active layer ACT overlaps the gate electrode GE may be the channel region of the active layer ACT.

The fourth insulating layer IL4 may be arranged on the third insulating layer IL3. In an embodiment, the fourth insulating layer IL4 may cover the gate electrode GE. In an embodiment, the fourth insulating layer IL4 may include an inorganic insulating material.

The source electrode SE and the drain electrode DE may be arranged on the fourth insulating layer IL4. In an embodiment, the source electrode SE and the drain electrode DE may include a conductive material. The source electrode SE and the drain electrode DE may be in contact with the active layer ACT. For example, the source electrode SE and the drain electrode DE may contact the active layer ACT through a hole penetrating the third insulating layer IL3 and the fourth insulating layer IL4 in the thickness direction (e.g., the third direction DR3).

The organic layer OL may be arranged on the fourth insulating layer IL4. The organic layer OL may provide a substantially flat upper surface. The organic layer OL may include an organic insulating material. A hole exposing the drain electrode DE may be formed in the organic layer OL.

The pixel electrode PXE may be arranged on the organic layer OL. In an embodiment, the pixel electrode PXE may include a conductive material. The pixel electrode PXE may contact the drain electrode DE through the hole penetrating the organic layer OL in the thickness direction (e.g., the third direction DR3). However, the pixel electrode PXE according to the embodiments of the present disclosure may not be limited thereto, and the pixel electrode PXE may contact the source electrode SE.

The pixel defining layer PDL may be arranged on the organic layer OL. In an embodiment, the pixel defining layer PDL may include an organic insulating material. The pixel defining layer PDL may partially cover the pixel electrode PXE. For example, the pixel defining layer PDL may expose the center of the pixel electrode PXE and may cover the edge of the pixel electrode PXE.

The light-emitting layer EML may be arranged on the pixel electrode PXE. In an embodiment, the light-emitting layer EML may include a light-emitting material such as an organic light-emitting material or quantum dots. The common electrode CE may be arranged on the light-emitting layer EML. In an embodiment, the common electrode CE may include a conductive material.

The encapsulation substrate ENC may be arranged on the display panel DP. The encapsulation substrate ENC may prevent impurities from penetrating into the light-emitting element EE. In an embodiment, the encapsulation substrate ENC may be a glass substrate. However, the encapsulation substrate ENC according to the embodiments of the present disclosure may not be limited thereto.

The protection layer PL may be arranged on the encapsulation substrate ENC. For example, the protection layer PL may be arranged on the encapsulation substrate ENC to prevent defects, such as dents or scratches, on the encapsulation substrate ENC.

The lower support layer SP may be arranged under the display panel DP. For example, the lower support layer SP may be arranged under the display panel DP to dissipate heat or reinforce rigidity. However, the lower support layer SP according to the embodiments of the present disclosure may not be limited thereto, and the lower support layer SP may be arranged to prevent phenomena, such as electromagnetic interference EMI or electrostatic discharge ESD.

However, the components included in the display device DD and the structure inside the display panel DP according to the embodiments of the present disclosure may not be limited thereto, and the inside of the display panel DP may have various modified structures, and the display device DD may further include other components in addition to the above-described components (e.g., the display panel DP, the encapsulation substrate ENC, the protection layer PL, and the lower support layer SP).

The display device according to the embodiment may be applied to various electronic devices. The electronic device according to an embodiment may include the above-described display device and may further include a module or a device having additional functions other than the display device.

FIG. 30 is a schematic diagram of various electronic devices to which the display device of FIG. 28 may be applied.

Referring to FIG. 30, various electronic devices to which the display device according to the embodiments is applied (e.g., the display device DD shown in FIG. 28) may include not only electronic devices for image display, such as a smartphone ED_1a, a tablet PC ED_1b, a laptop ED_1c, a TV ED_1d, and a desktop monitor ED_1e, but also wearable electronic devices including a display module, such as smart glasses ED_2a, a head-placed display ED_2b, and a smart watch ED_2c, and vehicle electronic devices including a display module, such as a CID Center Information Display arranged on an instrument panel, a center fascia, or a dashboard of a vehicle, and a room mirror display ED_3.

In an embodiment, the electronic device may include a display module, a processor, a memory, and a power module.

The processor may include at least one of a central processing unit CPU, an application processor AP, a graphic processing unit GPU, a communication processor CP, an image signal processor ISP, and a controller.

The memory may store data information required for the operation of the processor or the display module. When the processor executes an application stored in the memory, image data signals and/or input control signals may be transmitted to the display module, and the display module may process the received signals and output image information through a display screen.

The power module may include a power supply module, such as a power adapter or a battery device, and a power conversion module that converts power supplied from the power supply module to generate power necessary for operating the electronic device.

At least one of the components of the above-described electronic device may be included in the display device according to the above-described embodiments. In addition, from among the individual modules functionally included in one module, some may be included in the display device and others may be provided separately from the display device. For example, the display device may include the display module, and the processor, the memory, and the power module may be provided as other components within the electronic device rather than in the display device.

The electrostatic chuck, the substrate treating apparatus, and the method according to the embodiments may be applied to a display device included in a computer, a notebook, a mobile phone, a smartphone, a smart pad, a PMP, a PDA, an MP3 player, or the like.

Although the electrostatic chuck, the substrate treating apparatus, and the method according to the embodiments have been described with reference to the drawings, the illustrated embodiments are examples and may be modified and changed by a person having ordinary knowledge in the relevant technical field without departing from the technical spirit described in the following claims and their equivalents.

What is claimed is:

1. An electrostatic chuck comprising:
a body portion having a through hole;
a cushion layer on the body portion, a first inspection hole in the cushion layer overlapping the through hole in a plan view;
an electrode layer on the cushion layer, a second inspection hole in the electrode layer overlapping the first inspection hole in the plan view; and
a dielectric layer on the electrode layer and having a surface exposed through the second inspection hole, at least a portion of the dielectric layer being transparent.

2. The electrostatic chuck of claim 1, wherein the dielectric layer comprises a transparent polyimide.

3. The electrostatic chuck of claim 1, further comprising:
a first insulating layer between the cushion layer and the electrode layer;
a second insulating layer between the first insulation layer and the cushion layer;
a first adhesive layer between the dielectric layer and the electrode layer;
a second adhesive layer between the first insulating layer and the second insulating layer; and
a third adhesive layer between the cushion layer and the second insulating layer.

4. The electrostatic chuck of claim 3, wherein the through hole, the first inspection hole, and the second inspection hole connect to each other and extend from the body portion toward the surface of the dielectric layer.

5. The electrostatic chuck of claim 4, further comprising a transparent portion filling the through hole, the first inspection hole, and the second inspection hole, and contacting the surface of the dielectric layer,
wherein the transparent portion penetrates the electrode layer, the cushion layer, the first insulating layer, the second insulating layer, the first adhesive layer, the second adhesive layer, and the third adhesive layer.

6. The electrostatic chuck of claim 5, further comprising:
a first buffer pad in a space between the transparent portion and an inner surface of the body portion and surrounding the transparent portion in the plane view;
a first level adjuster under the transparent portion;
a second level adjuster under the first level adjuster; and
a third level adjuster under the second level adjuster and coupled to the second level adjuster and the body portion.

7. The electrostatic chuck of claim 6, wherein the body portion comprises a gas outlet, and
wherein the gas outlet penetrates a portion of the body portion, is connected to the space between the transparent portion and the inner surface of the body portion, and extends toward an outer surface of the body portion.

8. The electrostatic chuck of claim 3, wherein the through hole and the first inspection hole connect to each other and expose a surface of the second insulating layer, and
wherein the second inspection hole exposes a surface of the first insulating layer.

9. The electrostatic chuck of claim 8, wherein the second adhesive layer has a third inspection hole that overlaps the first inspection hole, in the plan view.

10. The electrostatic chuck of claim 9, wherein the first insulating layer has a first connecting hole that connects the second inspection hole and the third inspection hole, and
wherein the second insulating layer has a second connecting hole that connects the first inspection hole and the third inspection hole.

11. The electrostatic chuck of claim 10, wherein a size of the first connecting hole is less than a size of each of the second inspection hole and the third inspection hole, and
wherein a size of the second connecting hole is less than a size of each of the first inspection hole.

12. The electrostatic chuck of claim 8, further comprising a transparent portion filling the through hole and the first inspection hole and contacting the surface of the second insulating layer,
wherein the transparent portion penetrates the cushion layer and the second insulating layer.

13. A substrate treating apparatus comprising:
a process chamber having a space for processing a substrate;
a first electrostatic chuck in the process chamber comprising a first dielectric layer configured to receive a first target substrate and a first body portion having a first through hole overlapping the first dielectric layer;
a second electrostatic chuck in the process chamber configured to receive a second target substrate facing the first target substrate; and
a first imaging part outside the process chamber and configured to receive a location data of the first target substrate by a first light irradiated toward the first electrostatic chuck.

14. The substrate treating apparatus claim 13, wherein the first electrostatic chuck comprises:
a first cushion layer on the first body portion, the first cushion layer having a first inspection hole overlapping the first through hole in a plan view; and
a first electrode layer on the first cushion layer and overlapping the first inspection hole in the plan view, the first electrode layer having a second inspection hole extending to a surface of the first dielectric layer, and
wherein the first light is configured to irradiated toward the first through hole in the first electrostatic chuck, to pass through the first inspection hole and the second inspection hole, and to transmit through the first dielectric layer.

15. The substrate treating apparatus claim 14, wherein the second electrostatic chuck comprises:
a second dielectric layer configure to receive the second target substrate, at least a portion of the second dielectric layer being transparent;
a second body portion having a second through hole overlapping the second dielectric layer in the plan view;
a second cushion layer on the second body portion, the second cushion layer having a third inspection hole overlapping the second through hole in the plan view; and
a second electrode layer on the second cushion layer, the second cushion layer having a fourth inspection hole overlapping the third inspection hole in the plan view and extending a surface of the second dielectric layer.

16. The substrate treating apparatus claim 15, further comprising a second imaging part outside the process chamber and configured to receive a location data of the second target substrate by a second light irradiated toward the second electrostatic chuck,
wherein the second light is configured to be irradiated toward the second through hole of the second electrostatic chuck to pass through the third inspection hole and the fourth inspection hole and to transmit through the second dielectric layer.

17. A method of manufacturing a display device, the method comprising:
placing a first target substrate on a first dielectric layer of a first electrostatic chuck in a process chamber;
placing a second target substrate on a second dielectric layer of a second electrostatic chuck in the process chamber;
forming a vacuum state in a space inside the process chamber;
irradiating a first light toward the first electrostatic chuck from outside the process chamber and receiving a first image data comprising a location data of a first region of interest at where an alignment mark of the first target substrate is arranged;
determining whether or not the first target substrate is aligned based on the first image data; and
when the first target substrate is determined to be aligned, coupling the first target substrate and the second target substrate together.

18. The method of claim 17, wherein, in the receiving the first image data:
the first light is transmitted through the first electrostatic chuck and the first target substrate to reach the second target substrate, and
the first image data further comprises a location data of a second region of interest at where an alignment mark of the second target substrate is arranged.

19. The method of claim 18, further comprising determining whether or not the second target substrate is aligned based on the first image data.

20. The method of claim 17, further comprising:
irradiating a second light toward the second electrostatic chuck from outside the process chamber and receiving a second image data comprising a location data of a second region of interest at where an alignment mark of the second target substrate is arranged; and
determining whether or not the second target substrate is aligned based on the second image data.
